(19) United States
(12) Patent Application Publication
(10) Pub. No.: US 2026/0026033 A1
(43) Pub. Date: Jan. 22, 2026

(54) SEMICONDUCTOR DEVICES WITH ASYMMETRIC INSULATING LAYERS AND METHODS OF FABRICATION THEREOF

(71) Applicant: TEXAS INSTRUMENTS INCORPORATED, Dallas, TX (US)

(72) Inventors: Robert Cassel, Lehi, UT (US); Alexei Sadovnikov, Sunnyvale, CA (US); Jackson Bauer, Rowlett, TX (US); Joseph M. Khayat, Bedford, NH (US)

(21) Appl. No.: 18/773,953

(22) Filed: Jul. 16, 2024

(51) Int. Cl. H01L 29/78; H01L 21/308; H01L 29/06; H01L 29/66

(52) U.S. Cl. CPC H10D 30/65; H01L 21/308; H10D 30/0281; H10D 62/116

(57) ABSTRACT

Semiconductor devices and fabrication methods thereof are described. For example, a semiconductor device includes a semiconductor layer, a source region disposed in the semiconductor layer, a drain region disposed in the semiconductor layer, an insulating layer disposed in the semiconductor layer between the source region and the drain region, and a gate disposed over the semiconductor layer between the source region and the drain region, the gate covering a portion of the insulating layer. The insulating layer has a first sidewall extending toward the source region and a second sidewall extending toward the drain region, the first sidewall having a first slope and the second sidewall having a second slope greater than the first slope.

### TECHNICAL FIELD

The present disclosure relates to the field of semiconductor transistors, and more particularly, but not exclusively, to laterally diffused metal oxide semiconductor (LDMOS) transistors.

### BACKGROUND

LDMOS devices are field-effect transistors (FETs) designed for high power applications. In an LDMOS device, the drain and source have a relatively large spacing between them, as compared with MOS devices designed for other applications, and lateral diffusions are used to produce a well-controlled channel region under the gate. The operational performance of LDMOS devices is generally affected by parameters including, for example, a specific on-resistance (Rsp) and a breakdown voltage (BV). One design goal of LDMOS devices is to decrease Rsp and increase BV, or at least to improve one parameter without adversely affecting the other parameter.

### SUMMARY

The present disclosure describes semiconductor devices with asymmetric insulating layers and methods of fabrication thereof. This summary is not an extensive overview of the disclosure. Rather, a purpose of the summary is to present some examples of the present disclosure in a simplified form as a prelude to a more detailed description that is presented later.

In some examples, a semiconductor device includes a semiconductor layer, a source region disposed in the semiconductor layer, a drain region disposed in the semiconductor layer, an insulating layer disposed in the semiconductor layer between the source region and the drain region, and a gate disposed over the semiconductor layer between the source region and the drain region, the gate covering a portion of the insulating layer. The insulating layer has a first sidewall extending toward the source region and a second sidewall extending toward the drain region, the first sidewall having a first slope and the second sidewall having a second slope greater than the first slope.

In some other examples, a semiconductor device includes a semiconductor layer, a source region disposed in the semiconductor layer, a drain region disposed in the semiconductor layer, an asymmetric graded shallow trench isolation layer disposed in the semiconductor layer between the source region and the drain region, and a gate disposed over the semiconductor layer between the source region and the drain region, the gate covering a portion of the asymmetric graded shallow trench isolation layer. The asymmetric graded shallow trench isolation layer has a first sloped section extending toward the source region and a second sloped section extending toward the drain region.

In some additional examples, a method of fabricating a semiconductor device includes forming an insulating layer in a semiconductor layer, the insulating layer having a first sidewall extending toward a first side and a second sidewall extending toward a second side opposite the first side, the first sidewall having a first slope and the second sidewall having a second slope greater than the first slope. The method further includes forming a gate over the semiconductor layer, the gate covering a portion of the insulating layer, forming a source region in the semiconductor layer, the source region proximate to the first side, and forming a drain region in the semiconductor layer, the drain region proximate to the second side.

### BRIEF DESCRIPTION OF THE DRAWINGS

FIGS. 1A and 1B are cross-sectional views of semiconductor devices with asymmetric insulating layers in accordance with examples of the present disclosure;

FIGS. 2A-2L are cross-sectional views of a first process flow for forming asymmetric insulating layers of semiconductor devices in accordance with examples of the present disclosure;

FIGS. 3A-3L are cross-sectional views of a second process flow for forming asymmetric insulating layers of semiconductor devices in accordance with examples of the present disclosure; and

FIGS. 4A-4E are cross-sectional views of a third process flow for forming an asymmetric insulating layer of a semiconductor device in accordance with examples of the present disclosure.

### DETAILED DESCRIPTION

The present disclosure is described with reference to the attached figures. The components in the figures are not drawn to scale. Instead, emphasis is placed on clearly illustrating overall features and principles of the present disclosure. Numerous specific details and relationships are set forth with reference to examples of the figures to provide an understanding of the present disclosure. The figures and examples are not meant to limit the scope of the present disclosure to such examples, and other examples are possible by way of interchanging or modifying at least some of the described or illustrated elements. Moreover, where elements of the present disclosure can be partially or fully implemented using known components, certain portions of such components that facilitate an understanding of the present disclosure are described, and detailed descriptions of other portions of such components are omitted so as not to obscure the present disclosure.

As used herein, terms such as “first” and “second” are used to arbitrarily distinguish between the elements such terms describe. Thus, these terms in the description and in the claims are not intended to indicate temporal or other prioritization of such elements. Moreover, terms such as “front,” “back,” “top,” “bottom,” “over,” “under,” “vertical,” “horizontal,” “lateral,” “down,” “up,” “upper,” “lower,” or the like, are used to refer to relative directions or positions of features in devices in view of the orientation shown in the figures. For example, “upper” or “uppermost” can refer to a feature positioned closer to the top of a page than other features. The terms so used are interchangeable under appropriate circumstances such that the examples and illustrations of the technology described herein are, for example, capable of operation in other orientations than those illustrated or otherwise described herein. In the following discussion and in the claims, the terms “including,” “includes,” “having,” “has,” “with,” or variants thereof are intended to be inclusive in a manner similar to the term “comprising,” and thus should be interpreted to mean, for example, “including, but not limited to.” Further, in some examples, the terms “about,” “approximately,” or “substantially” preceding a value mean+/−10-20 percent of the stated value. Still further, unless otherwise specified, the ordering of steps in the description and in the claims are not intended to limit sequencing of the performance of steps and thus alternate step sequencing is contemplated as appropriate.

Various structures disclosed herein can be formed using semiconductor process techniques. Layers including a variety of materials can be formed over a substrate (e.g., a semiconductor wafer), for example, using deposition techniques (e.g., chemical vapor deposition, physical vapor deposition, atomic layer deposition, spin coating, plating), thermal process techniques (e.g., oxidation, nitridation, epitaxy), and/or other suitable techniques. Similarly, some portions of the layers can be selectively removed, for example, using etching techniques (e.g., plasma (or dry) etching, wet etching), chemical mechanical planarization, and/or other suitable techniques, some of which may be combined with photolithography steps. The conductivity (or resistivity) of the substrate (or regions of the substrate) can be controlled by doping techniques using various chemical species (which may also be referred to as dopants, dopant atoms, or the like) including, but not limited to, boron, gallium, indium, arsenic, phosphorus, or antimony. Doping may be performed during the initial formation or growth of the substrate (or an epitaxial layer grown on the substrate), by ion-implantation, or other suitable doping techniques.

As mentioned, the operational performance of an LDMOS device is generally affected by a tradeoff between a specific on-resistance (Rsp) parameter and a breakdown voltage (BV) parameter. For example, design approaches that seek to achieve the advantage of a higher BV by increasing the body area of the device consequently lead to the disadvantage of a higher Rsp. Similarly, design approaches that seek to decrease Rsp generally come at the cost of decreasing the BV rating. Accordingly, LDMOS design approaches that effectively manage this tradeoff provide technical advantages.

LDMOS and other power devices may utilize field relief dielectrics for tuning the Rsp and BV parameters. In some examples, field relief dielectrics for LDMOS and other power devices include local oxidation of silicon (LOCOS), shallow trench isolation (STI), and abrupt or sharp-edge step gate approaches. The LOCOS approach forms a field relief dielectric with a bird's beak with tapered corners near a hard mask edge leading to a weak point for breakdown and hot carriers. The bird's beak benefits the field relief at the expense of increased Rsp. Further, the symmetric nature of LOCOS leaves a thin field oxide on the drain side. While the LOCOS approach provides some depth scaling, due to aspect ratio impacts, the depth scaling is controllable over only a limited range of LOCOS critical dimensions. The STI and step gate approaches tend to result in sharp corners, which create weak points for breakdown and hot carriers. Further, adequate control of the thickness of the field relief dielectric may not be feasible with the above-described approaches.

Semiconductor devices, such as LDMOS devices, are described herein which allow for improved Rsp while reducing device area. In some examples, this and other technical advantages may be achieved through introduction of an insulating layer (also referred to as a field relief dielectric) that has a smooth, shallow slope on the side that extends toward the source, and a steeper slope on the side that is away from the source. Thus, the insulating layer is asymmetric and may be referred to, in at least some examples, as an asymmetric insulating layer, an asymmetric graded STI layer, an asymmetric graded STI structure, etc. The asymmetric insulating layer has an adjustable slope and lateral scaling characteristics, such that relatively low voltage (LV) and relatively high voltage (HV) LDMOS devices can be formed in different regions of a wafer or other structure. The asymmetric insulating layers for relatively LV and relatively HV LDMOS devices may have different trench lengths (e.g., measured in a direction of current flow between source and drain of LDMOS devices) while maintaining the same trench depth. The sloped profile of the asymmetric insulating layer leads to improved Rsp, while also providing reduced device area due to the asymmetric shape.

In some examples, a semiconductor device includes a semiconductor layer, a source region disposed in the semiconductor layer, a drain region disposed in the semiconductor layer, and an asymmetric insulating layer (e.g., a field relief dielectric) disposed in the semiconductor layer between the source region and the drain region. The asymmetric insulating layer has a first sidewall that extends toward the source region and a second sidewall that extends toward the drain region. The first sidewall has a first slope and the second sidewall has a second slope greater than the first slope. The semiconductor device also includes a gate disposed over the semiconductor layer between the source region and the drain region, the gate covering a portion of the asymmetric insulating layer. The asymmetric insulating layer may include a dielectric material selected to provide field relief. The asymmetric insulating layer may be formed of an oxide material, a nitride material, combinations thereof, etc. At least a portion of the gate may extend past an edge of the asymmetric insulating layer towards the source region. At least a portion of the asymmetric insulating layer may extend past an edge of the gate towards the drain region. The first sidewall of the asymmetric insulating layer may have a first length (e.g., measured in a direction of current flow between the source and drain regions), and the second sidewall of the asymmetric insulating layer may have a second length that is less than the first length. The asymmetric insulating layer may include a non-sloped portion (e.g., a horizontal or flat portion, with a slope at or about zero degrees) that extends between the first sidewall and the second sidewall.

The asymmetric insulating layer may provide a shallow trench isolation (STI) region, and may be referred to as an asymmetric STI layer (or an asymmetric STI structure), a graded STI layer (or a graded STI structure), or an asymmetric graded STI layer (or an asymmetric graded STI structure). The asymmetric graded STI layer has a first sloped section (e.g., a shallow-sloped section) that extends toward the source region and a second sloped section (e.g., a steep-sloped section) that extends toward the drain region. The first sloped section of the asymmetric graded STI layer may have a first length (e.g., measured in a direction of current flow between the source and drain regions), and the second sloped section of the asymmetric graded STI layer may have a second length less than the first length. The asymmetric graded STI layer may include a non-sloped section (e.g., a horizontal or flat portion, with a slope at or about zero degrees) between the first sloped section and the second sloped section. A first slope of the first sloped section of the asymmetric graded STI layer is different than a second slope of the second sloped section of the graded STI layer, where the second slope is greater than the first slope.

Methods for fabricating semiconductor devices, such as LDMOS devices, include forming an asymmetric insulating layer in a semiconductor layer, where the asymmetric insulating layer has a first sidewall extending toward a first side and a second sidewall extending toward a second side opposite the first side, the first sidewall having a first slope and the second sidewall having a second slope greater than the first slope. The methods also include forming a gate over the semiconductor layer, the gate covering a portion of the asymmetric insulating layer, forming a source region in the semiconductor layer, the source region proximate to the first side, and forming a drain region in the semiconductor layer, the drain region proximate to the second side.

Moreover, forming the asymmetric insulating layer may include forming a first hard mask layer over the semiconductor layer, forming a second hard mask layer over the first hard mask layer, forming a first patterning layer over a portion of the second hard mask layer, etching exposed portions of the second hard mask layer, and removing the first patterning layer. In some examples, forming the asymmetric insulating layer may further include forming a second patterning layer over a portion of the first hard mask layer, where an edge of the second patterning layer proximate the second hard mask layer defines an edge of the first sidewall of the asymmetric insulating layer proximate the second side, performing two or more iterations of (i) performing a partial etch of an exposed portion of the first hard mask layer and (ii) laterally trimming the second patterning layer to expose an additional portion of the first hard mask layer, removing the second patterning layer, transferring a pattern of the first hard mask layer to a trench in the semiconductor layer, and forming insulating material for the asymmetric insulating layer in the trench.

In other examples, forming the asymmetric insulating layer may further include forming a second patterning layer over the first hard mask layer and a portion of the second hard mask layer, where an edge of the second patterning layer proximate the second hard mask layer defines an edge of the first sidewall of the asymmetric insulating layer proximate the second side, performing two or more iterations of (i) performing a partial etch of exposed portions of the first hard mask layer and the second hard mask layer and (ii) laterally trimming the second patterning layer to expose an additional portion of at least one of the first hard mask layer and the second hard mask layer, removing the second patterning layer, transferring a pattern of the first hard mask layer to a trench in the semiconductor layer, and forming insulating material for the asymmetric insulating layer in the trench.

Forming the asymmetric insulating layer may alternatively include forming a photoresist layer over the semiconductor layer, generating a pattern in the photoresist layer utilizing a mask device comprising a light-passing substrate and a patterned opaque layer disposed on the light-passing substrate, where the patterned opaque layer includes a light modulating region defining the first slope of the first sidewall and the second slope of the second sidewall, transferring the pattern of the photoresist layer to a trench in the semiconductor layer, and forming insulating material for the asymmetric insulating layer in the trench. The light modulating region includes a set of features, wherein at least a subset of the set of features are disposed at differing distances from one another for defining at least one of the first slope of the first sidewall and the second slope of the second sidewall.

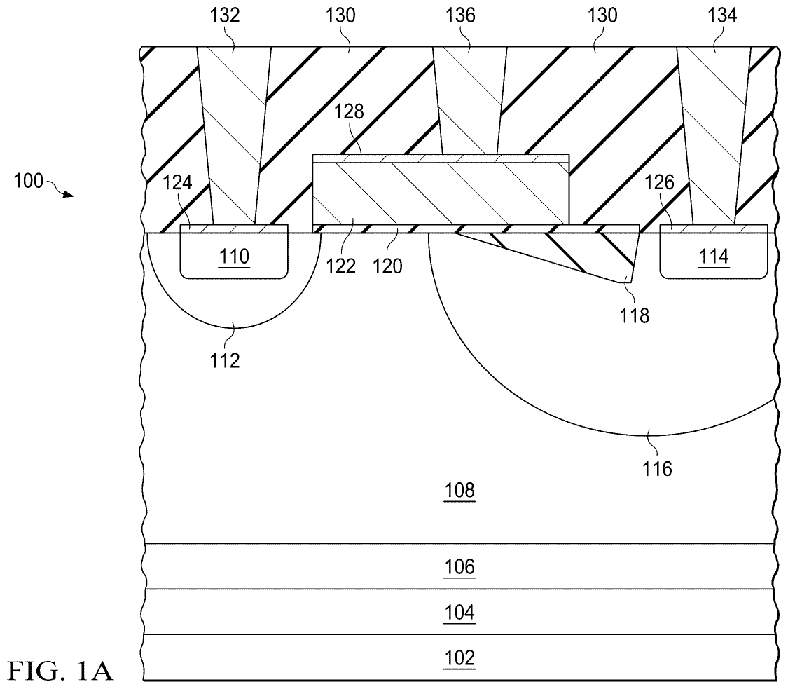

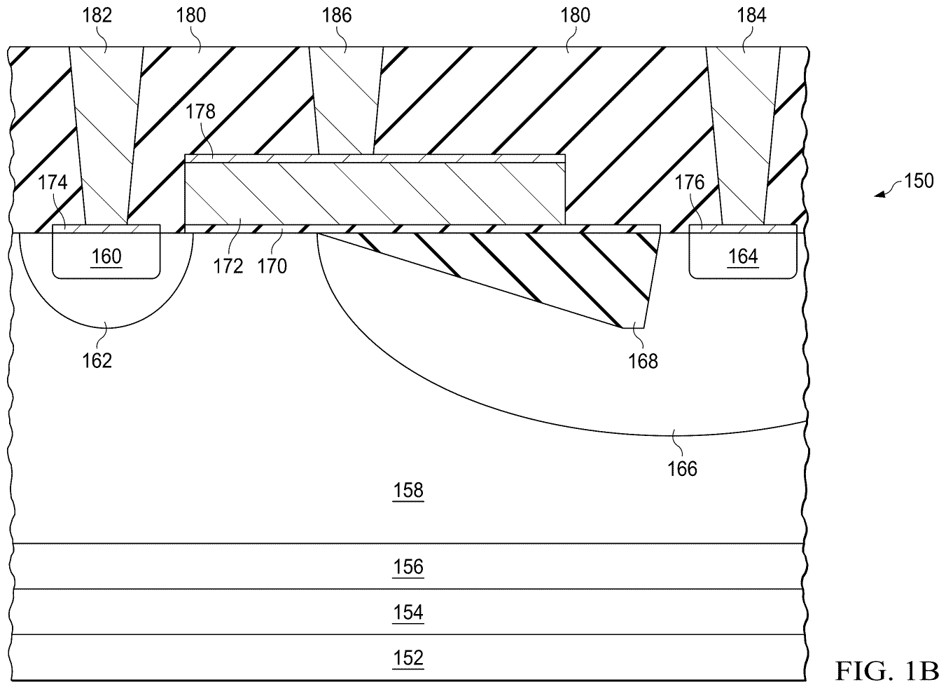

Referring now to FIG. 1A, a cross-sectional view of an LDMOS device 100 is shown. The LDMOS device 100 includes a substrate 102, a first buried layer 104, a second buried layer 106, and a semiconductor layer 108, e.g., formed by an epitaxial process in some examples, and thus referred to as an epitaxial or “epi” layer 108 in such examples. The LDMOS device 100 also includes a source region 110 and a well region 112. The well region 112 is disposed in the epi layer 108, and the source region 110 is disposed in the well region 112. The LDMOS device 100 further includes a drain region 114 and a drain drift region 116. The drain drift region 116 is disposed in the epi layer 108, and the drain region 114 is disposed in the drain drift region 116. The LDMOS device 100 further includes a first insulating layer 118, a second insulating layer 120, and a gate 122. The first insulating layer 118 is asymmetric, and may also be referred to as an asymmetric graded STI layer 118. The asymmetric graded STI layer 118 is disposed in the epi layer 108 within the drain drift region 116. The second insulating layer 120, which may be referred to as a gate dielectric or a gate insulator 120, is disposed between the gate 122 and the epi layer 108. A channel region may be considered to extend across a portion of the epi layer 108 under the gate 122 between the source region 110 and the drain region 114.

In some examples, the substrate 102, the second buried layer 106, the epi layer 108 and the well region 112 have a first conductivity (e.g., one of p-type and n-type), while the first buried layer 104, the source region 110, the drain region 114 and the drain drift region 116 have a second conductivity (e.g., the other of p-type and n-type). While two buried layers, e.g., the first buried layer 104 and the second buried layer 106, are shown, other examples may include one or the other of the buried layers, or no buried layer at all.

The gate 122 is disposed over the gate insulator 120 and at least a portion of the asymmetric graded STI layer 118. In some examples, the gate 122 is a polysilicon material. In other examples, the gate 122 is a metal or other suitable material. As shown in FIG. 1A, the gate 122 extends past a first edge of the asymmetric graded STI layer 118 towards the source region 110. In some examples, a second edge of the asymmetric graded STI layer 118 extends past an edge of the gate 122 towards the drain region 114. In other examples, the second edge of the asymmetric graded STI layer 118 does not extend past the edge of the gate 122 towards the drain region 114. Thus, the gate 122 may terminate closer to the source region 110 or the drain region 114 than shown in FIG. 1A. In some examples, the gate 122 may terminate adjacent the source region 110 and/or the drain region 114, rather than being spaced apart from the source region 110 and/or the drain region 114 as shown in FIG. 1A.

Silicide layers 124, 126 and 128 are disposed in contact with the source region 110, the drain region 114 and the gate 122, respectively. The silicide layers 124, 126 and 128 provide ohmic contacts and high conductivity.

An interlayer dielectric (ILD) 130 is disposed over the structure, and conductive vias 132, 134 and 136 are disposed in the ILD 130 to contact the silicide layers 124, 126 and 128, respectively.

Referring now to FIG. 1B, a cross-sectional view of an LDMOS device 150 is shown. LDMOS device 150 may be considered a device for higher voltage applications than LDMOS device 100, as further described below. The LDMOS device 150 includes a substrate 152, a first buried layer 154, a second buried layer 156, and a semiconductor layer 158, e.g., formed by an epitaxial process in some examples, and thus referred to as an epitaxial or “epi” layer 158 in such examples. The LDMOS device 150 also includes a source region 160, a well region 162, a drain region 164, a drain drift region 166, a first insulating layer 168 also referred to as an asymmetric graded STI layer 168, and a second insulating layer 170 also referred to as a gate dielectric or a gate insulator 170, disposed between a gate 172 and the epi layer 158. A channel region may be considered to extend across a portion of the epi layer 158 under gate 172 between the source region 160 and the drain region 164. The LDMOS device 150 further includes silicide layers 174, 176 and 178 disposed in contact with the source region 160, the drain region 164 and the gate 172, respectively. An ILD 180 is disposed over the structure, and conductive vias 182, 184 and 186 are disposed in the ILD 180 to contact the silicide layers 174, 176 and 178, respectively.

The substrate 152, the first buried layer 154, the second buried layer 156, the epi layer 158, the source region 160, the well region 162, the drain region 164, the drain drift region 166, the gate insulator 170, the gate 172, the silicide layers 174, 176 and 178, the ILD 180, and the conductive vias 182, 184 and 186 are similar to the substrate 102, the first buried layer 104, the second buried layer 106, the epi layer 108, the source region 110, the well region 112, the drain region 114, the drain drift region 116, the gate insulator 120, the gate 122, the silicide layers 124, 126 and 128, the ILD 130, and the conductive vias 132, 134 and 136, respectively.

The asymmetric graded STI layer 168 may be formed of similar materials as the asymmetric graded STI layer 118, but has a different shape. The asymmetric graded STI layer 118 and the asymmetric graded STI layer 168 have a same depth, but different lateral lengths (e.g., measured in a direction of current flow between the source and drain regions). The asymmetric graded STI layer 168 includes a longer non-sloped portion (e.g., a horizontal or flat portion, with a slope at or about zero degrees) than the asymmetric graded STI layer 118, providing a greater area for distributing electric field during operation such that that the asymmetric graded STI layer 168 is more suited for use with relatively high voltage (HV) applications. In examples, the LDMOS device 100 is a relatively low voltage (LV) LDMOS device, while the LDMOS device 150 is a relatively HV LDMOS device. The LDMOS device 100 and the LDMOS device 150, in some examples, are formed on different portions of a same wafer or semiconductor structure (e.g., such that the substrates 102 and 152 are the same, as well as possibly other layers such as the ILDs 130 and 180). For LDMOS devices designed for relatively HV use, the lateral sizing of the asymmetric graded STI layer 168 (e.g., with the longer non-sloped portion between the first sloped sidewall that extends toward the source region 160 and the second sloped sidewall that extends toward the drain region 164) provides improved Rsp and BV characteristics. The lateral scaling of an asymmetric graded STI layer may be based on the expected voltage or power requirements of LDMOS devices.

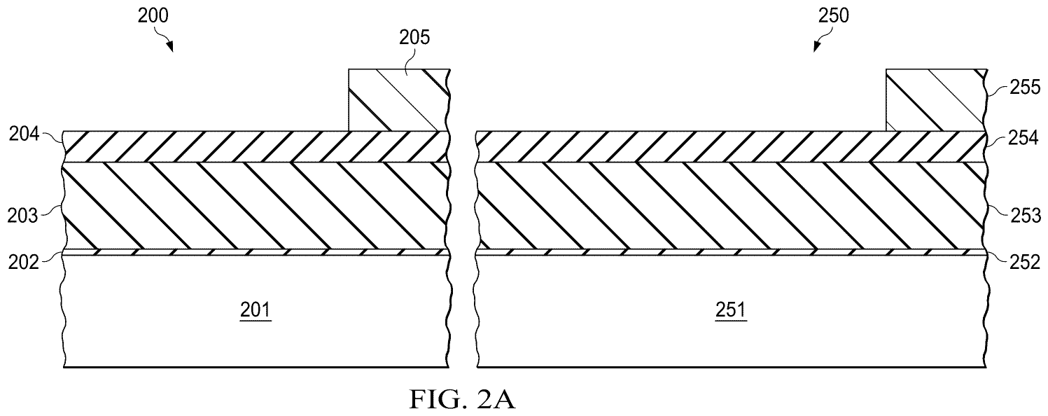

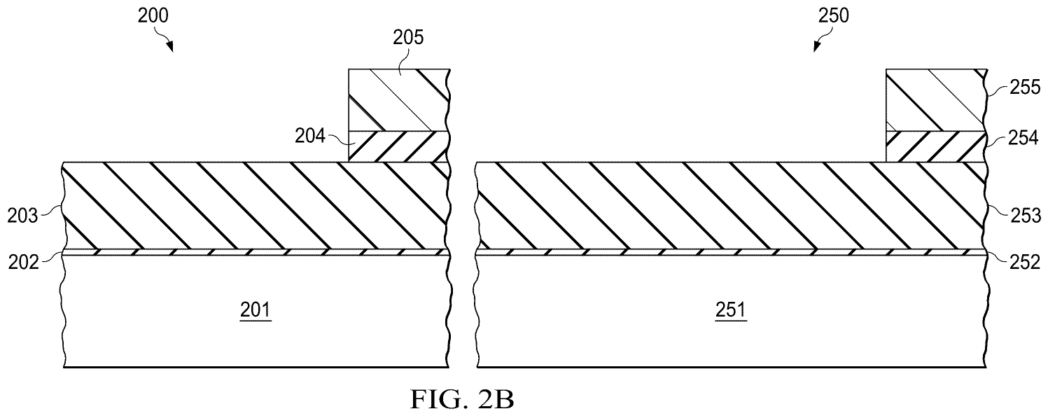

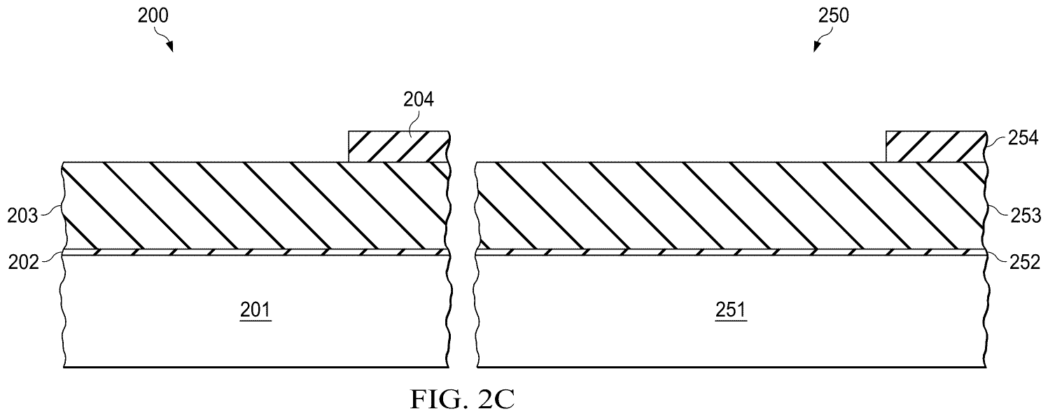

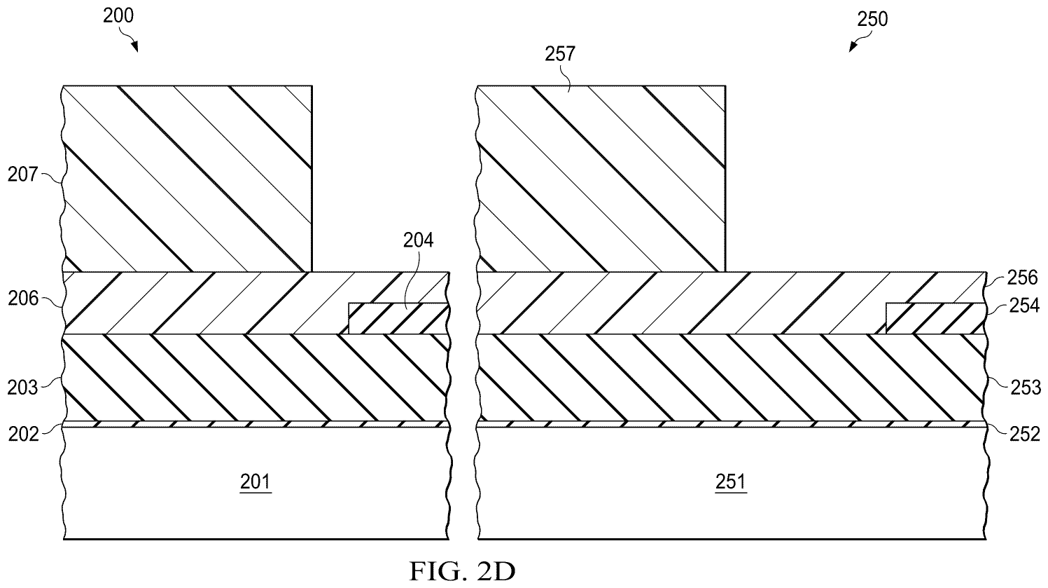

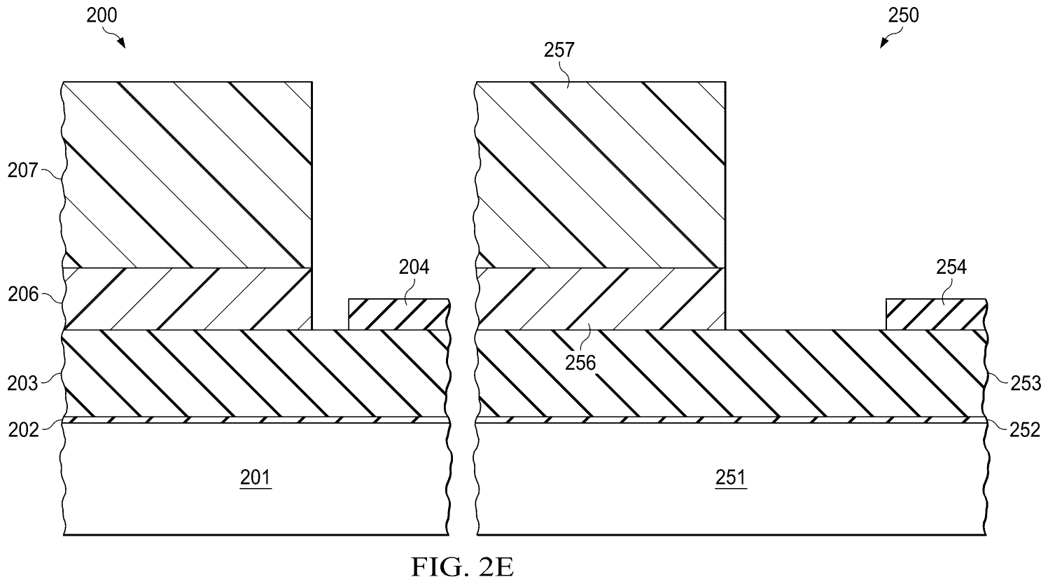

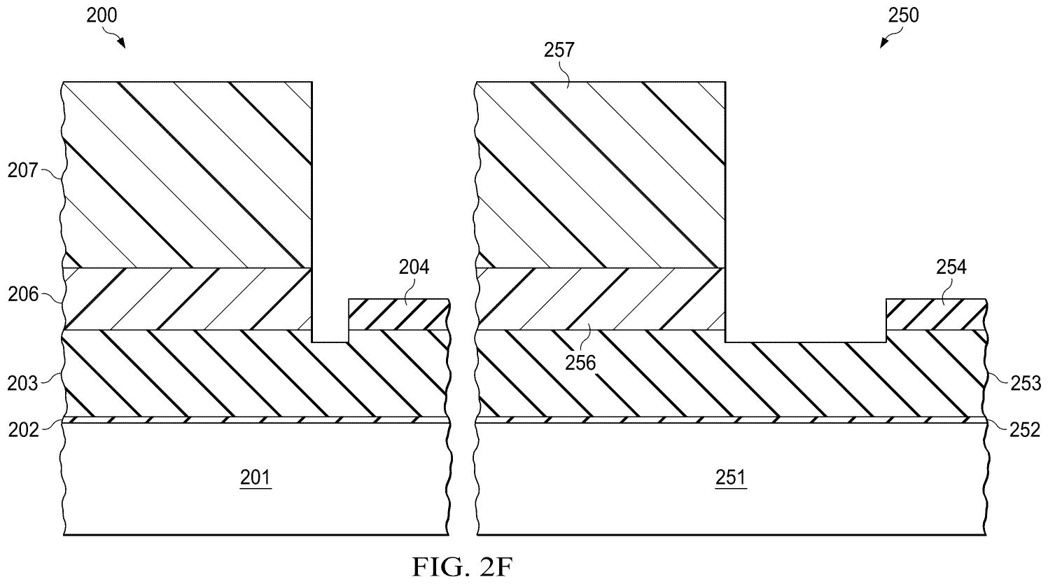

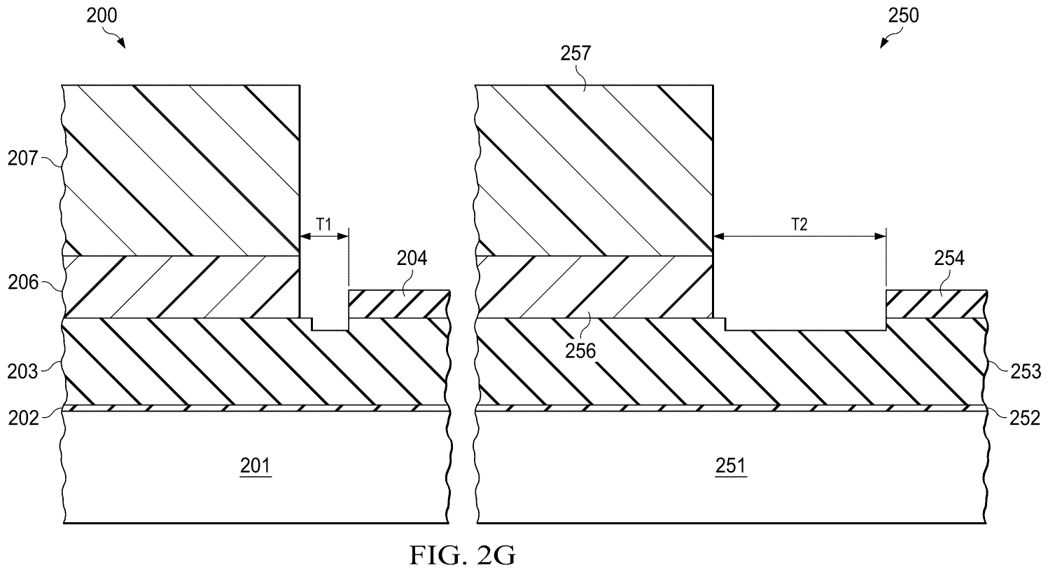

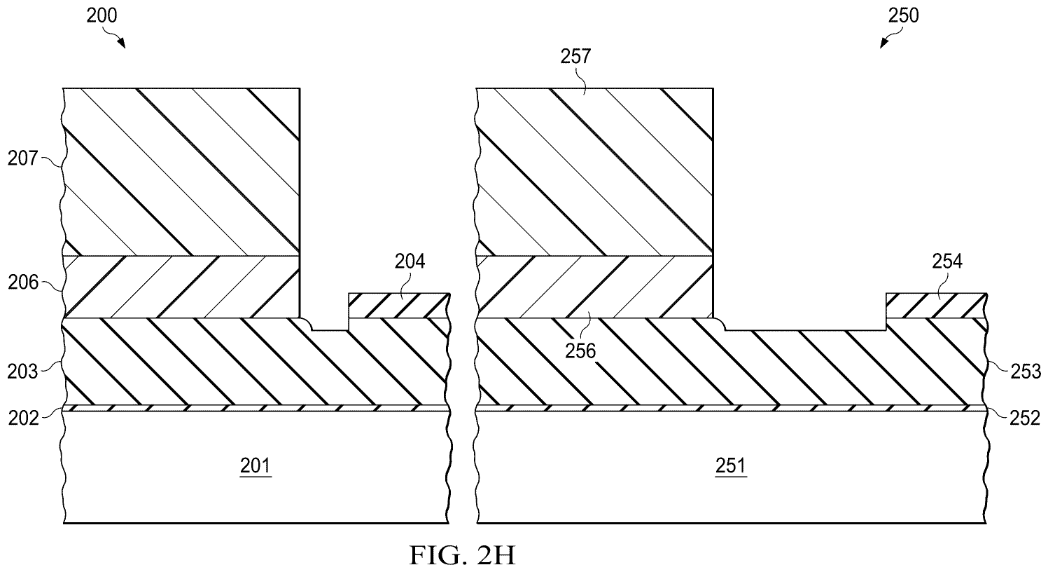

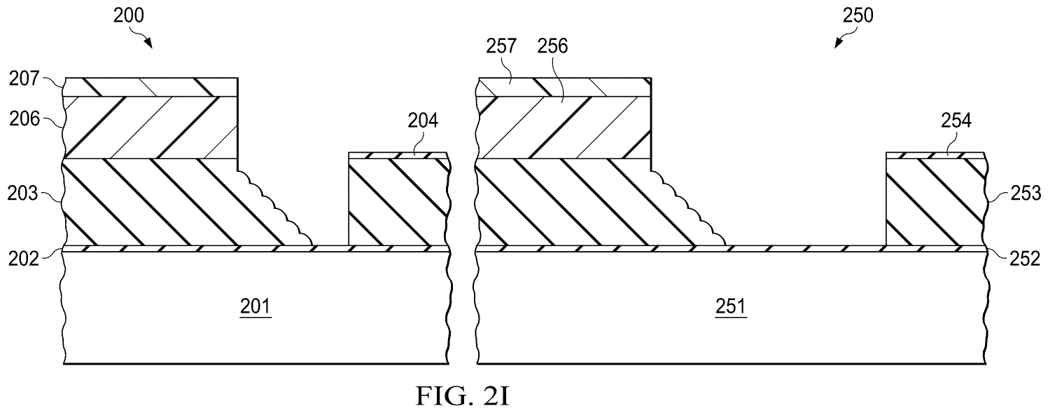

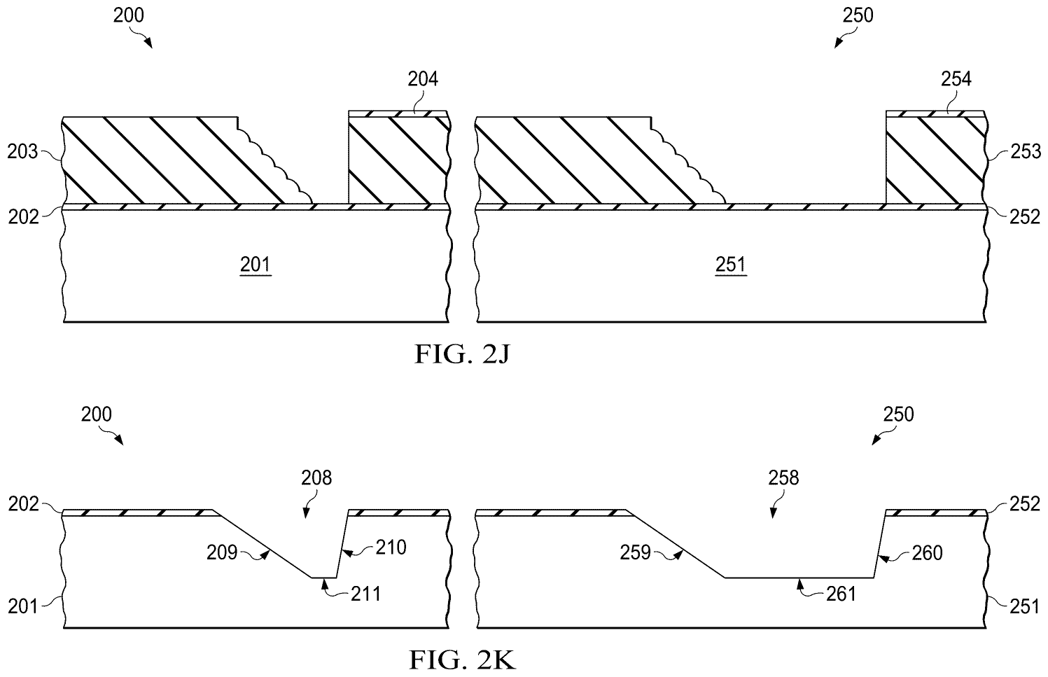

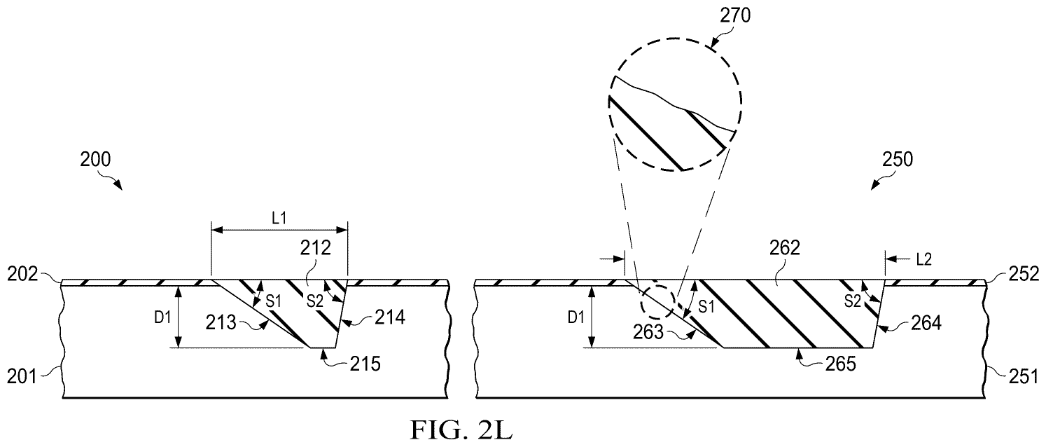

Semiconductor structures with asymmetric graded STI layers may be formed using various processing flows. In some examples (e.g., the processing flow described in further detail below with respect to FIGS. 2A-2L), two masks are used to achieve the asymmetric shape of asymmetric graded STI layers—a first mask which is used to pattern the steep edges (e.g., the sidewalls extending away from the source regions) and a second mask which is used to pattern the shallow edges (e.g., the sidewalls extending toward the source regions). The second mask may be used in a cyclic trim-and-etch process for forming a staircase-like profile in a hard mask layer that is later transferred to a semiconductor layer to form a trench where an asymmetric graded STI layer will be formed. The shallow edge of the asymmetric graded STI layer has a slope which is optimized for lower voltage devices. Higher voltage devices formed on the same wafer or other structure would share the same slope on the shallow edge (as well as the same depth), but have flat portions (e.g., non-sloped portions between the steep edge and the shallow edge) which are extended laterally (e.g., the asymmetric graded STI layer 168 is extended laterally relative to the asymmetric graded STI layer 118). The trench shapes of asymmetric graded STI layers are patterned into a hard mask layer, and then transferred to an underlying semiconductor layer (e.g., epi layer 108 or epi layer 158)—e.g., based on a plasma etch process. The natural faceting of a plasma etch processing will result in smoothing of the staircase-like profile during this transfer step. Additional smoothing may be achieved with in-situ steam generation (ISSG) liner processing for forming the asymmetric graded STI layers in the trenches formed in the semiconductor layer.

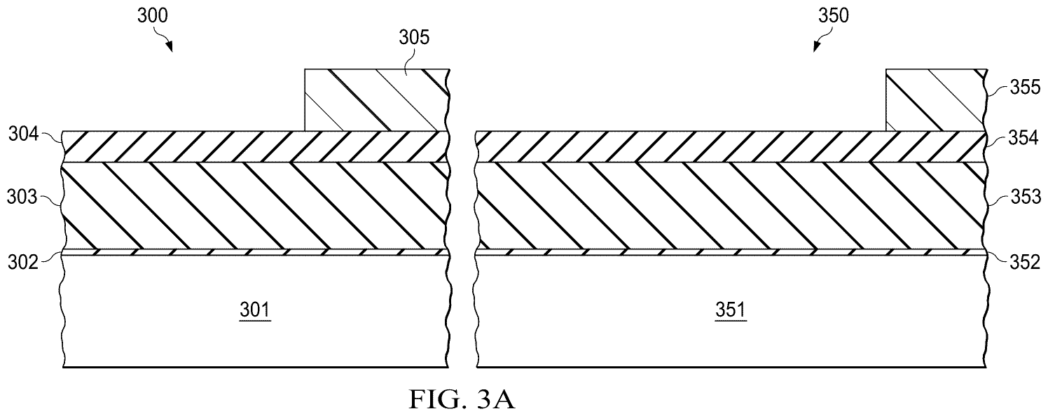

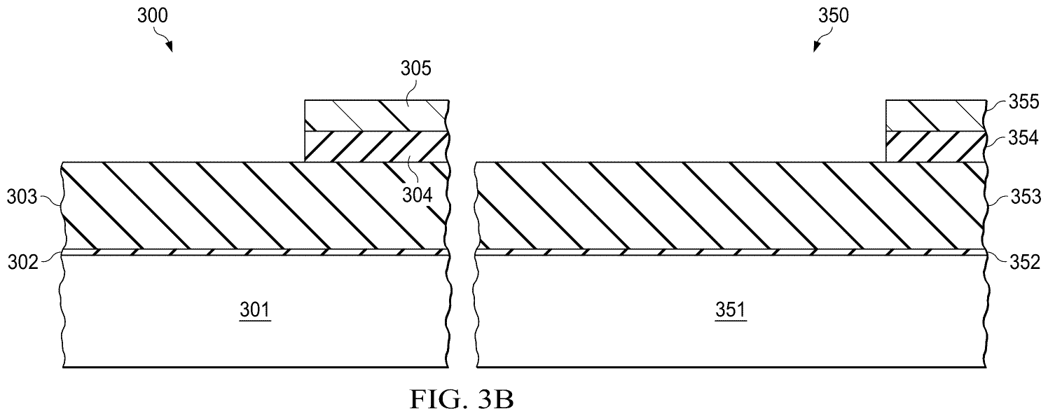

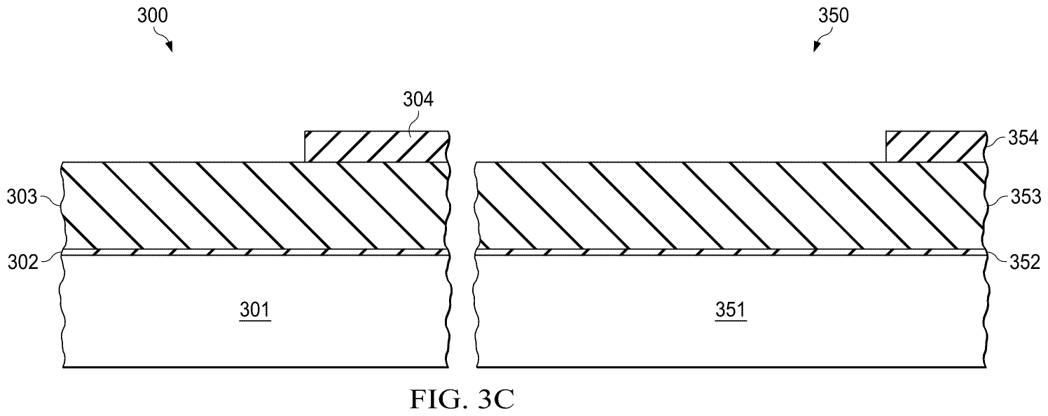

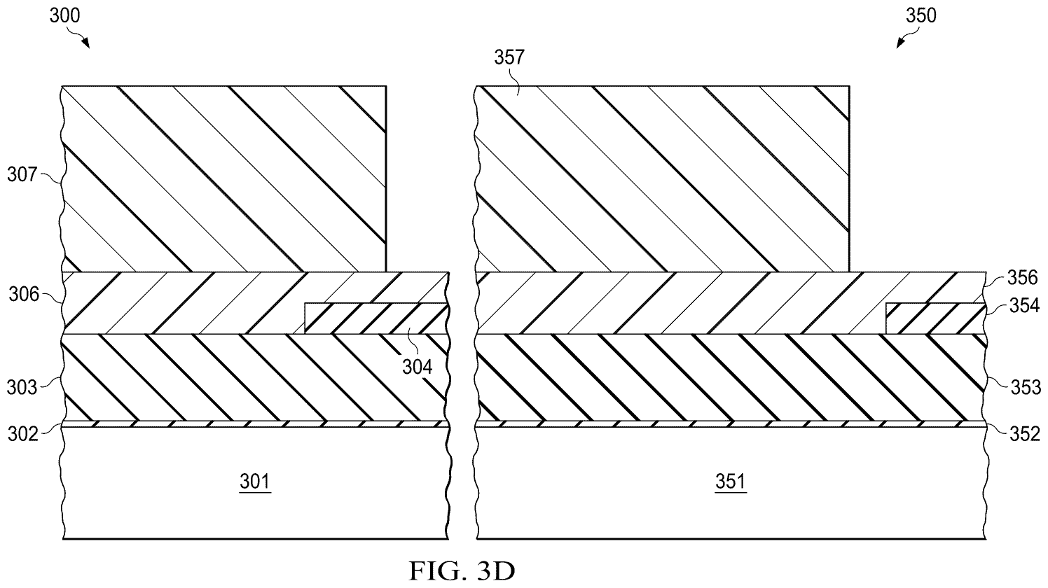

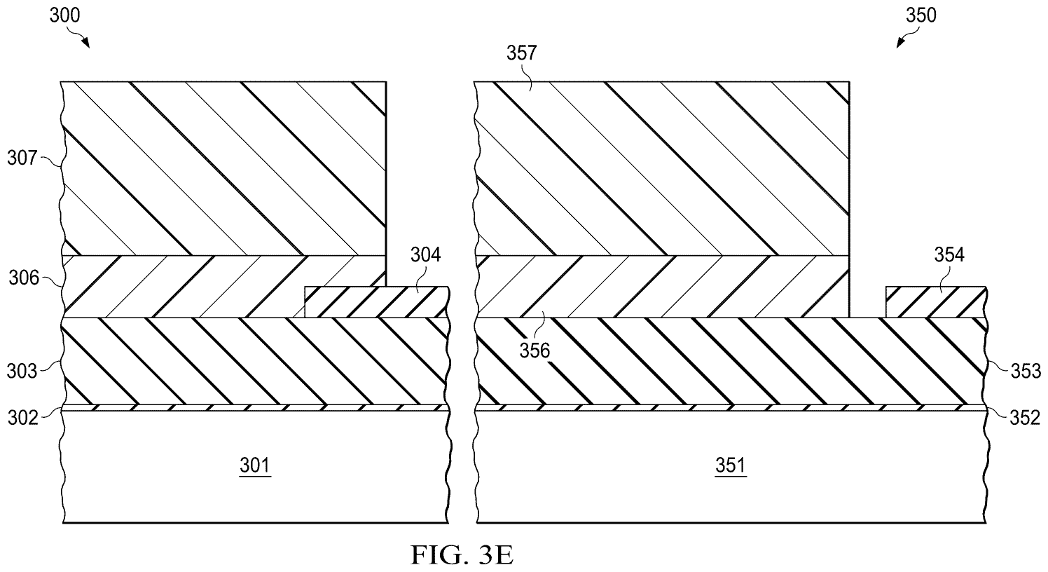

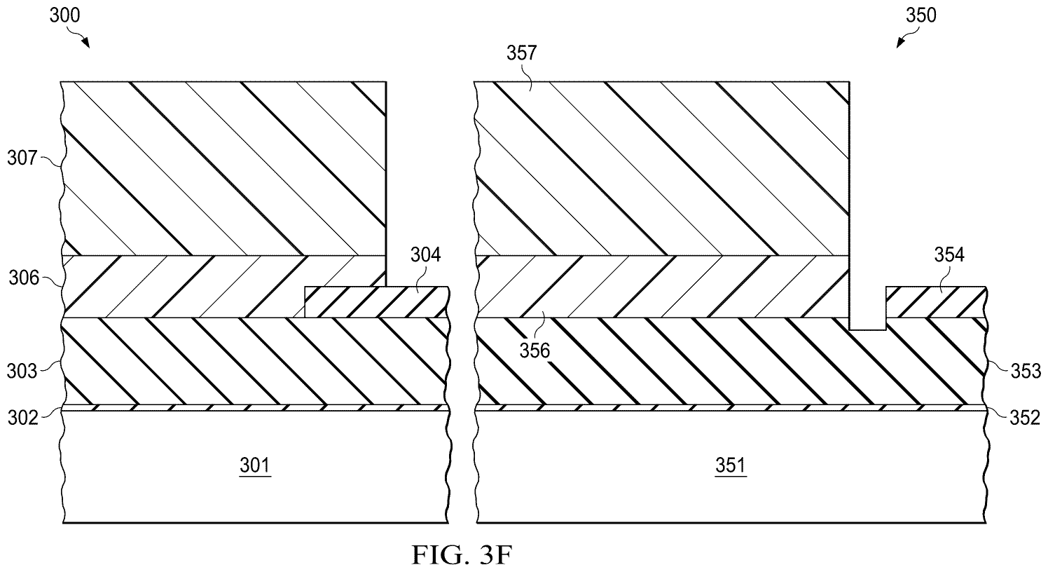

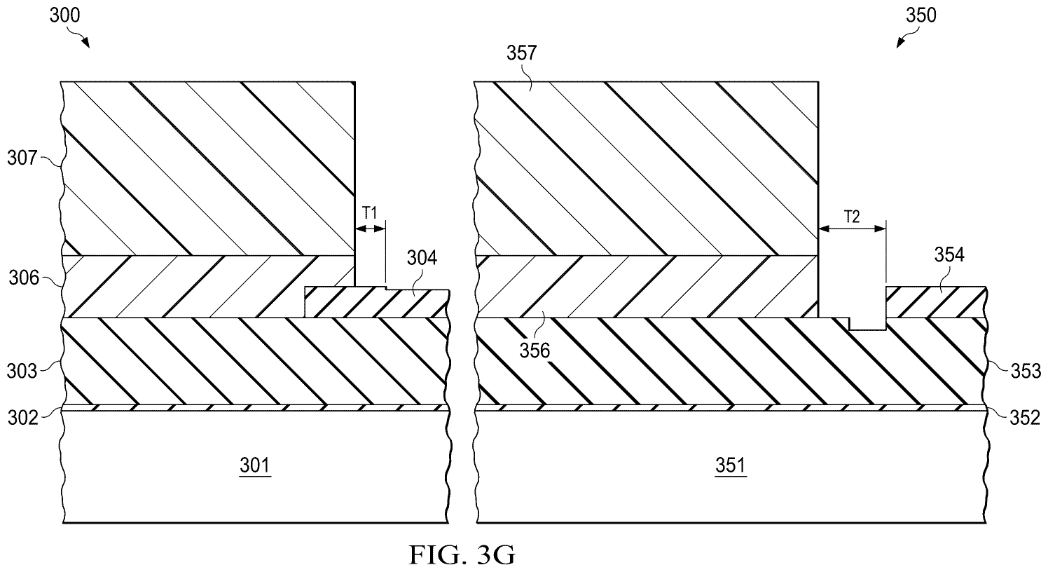

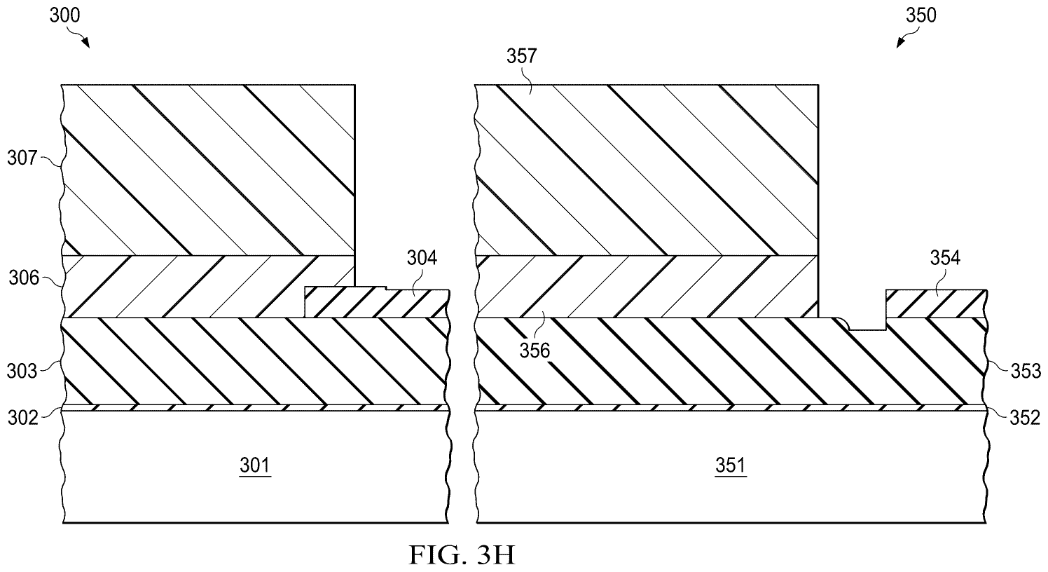

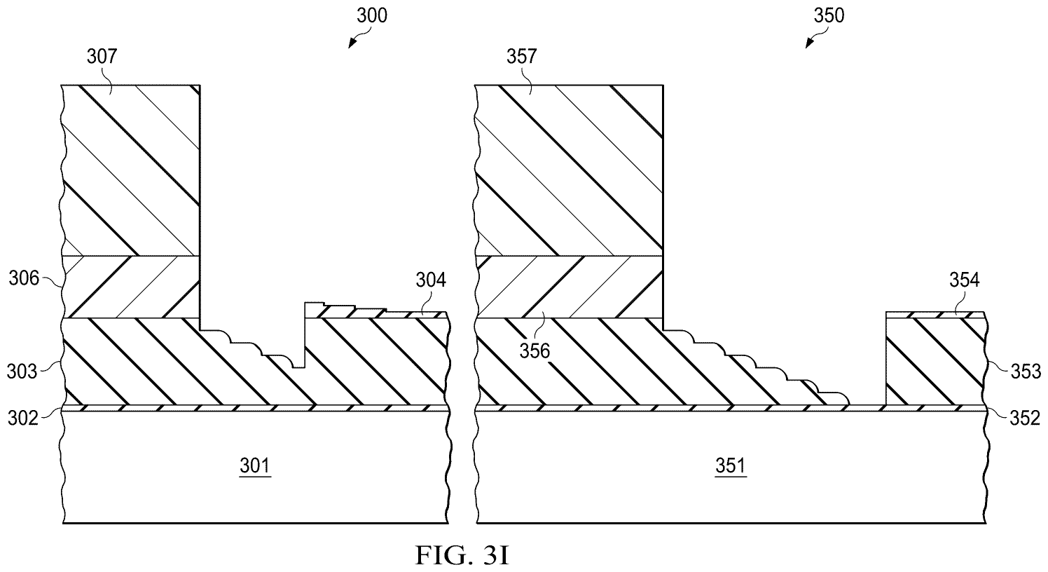

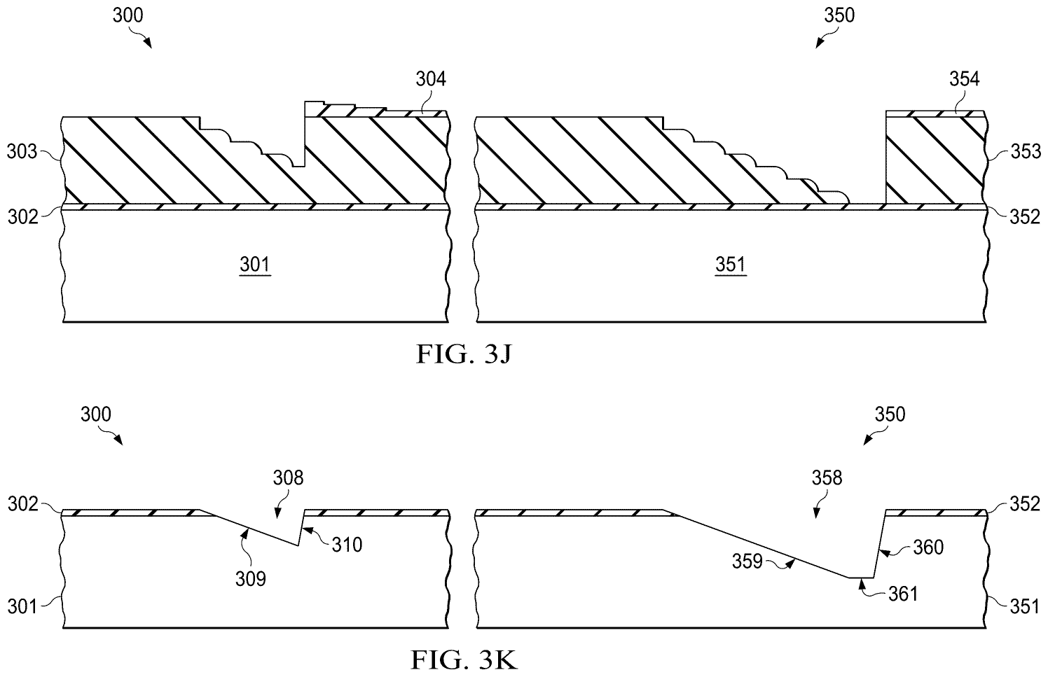

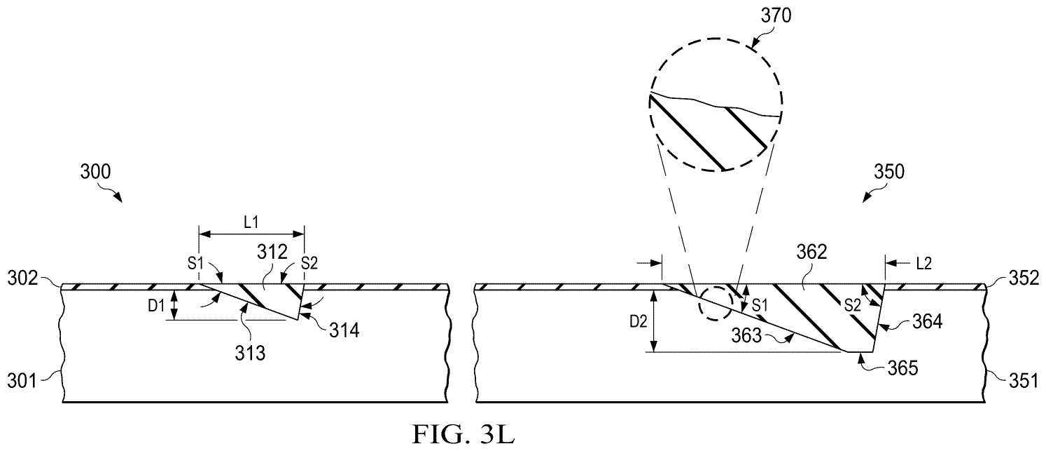

In other examples (e.g., the processing flow shown in FIGS. 3A-3L), two masks are also used to achieve the asymmetric shape of the asymmetric graded STI layers—a first mask which is used to pattern the steep edges (e.g., the sidewalls extending away from the source regions) and a second mask which is used to pattern the shallow edges (e.g., the sidewalls extending toward the source regions). In such other examples, LV and HV devices may have different trench depths as a result of having the first mask overlap the second mask.

The edge of a first pattern (e.g., photoresist) and an inorganic hard mask is used to create the steep slope on the drain side of a trench for an asymmetric graded STI layer. The edge of a second pattern (e.g., photoresist) and an organic mask are used with a cyclic trim and etch process to create the staircase-type shallow slope on the source side of the trench for the asymmetric graded STI layer. The trench is then transferred from the mask into an underlying semiconductor layer (e.g., based on a plasma etch process), which smooths the staircase-like profile of the shallow slope. In examples, both LV and HV devices will have the same shallow and steep slopes, but the HV devices will have an extended flat or non-sloped region.

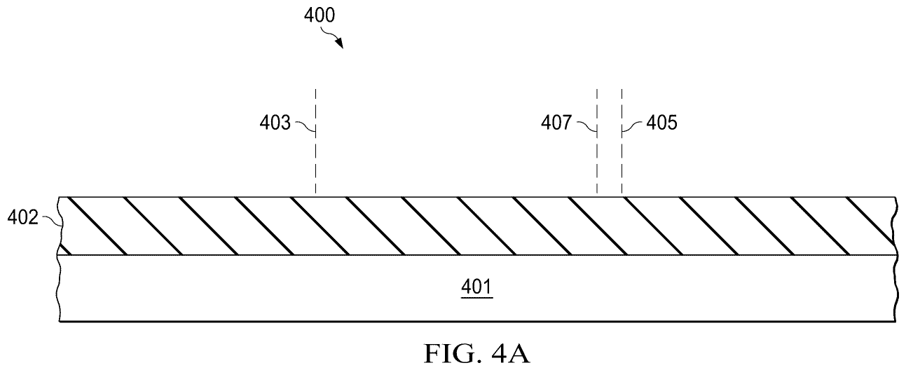

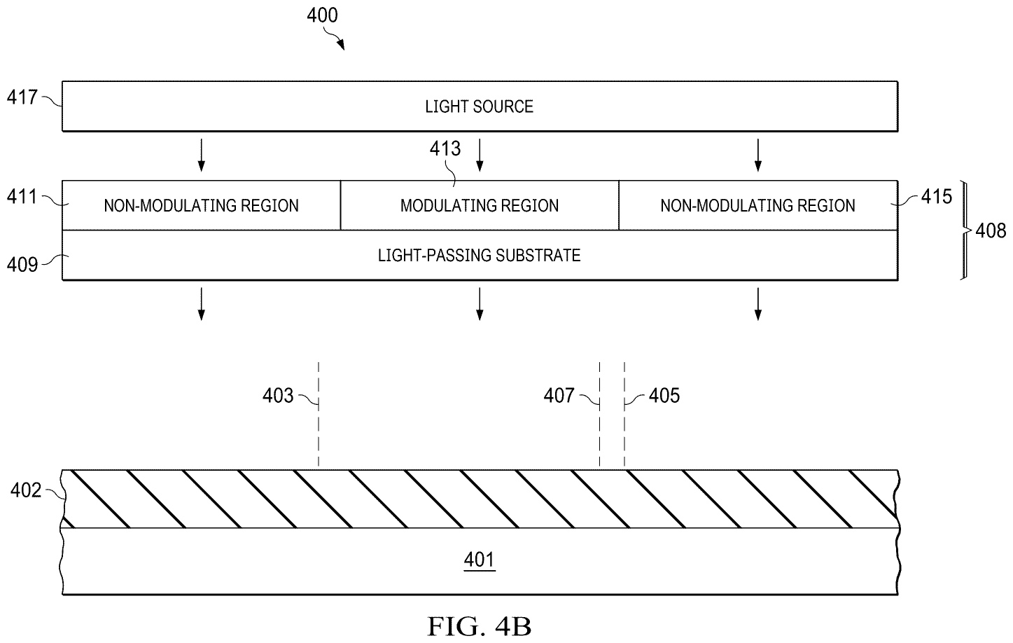

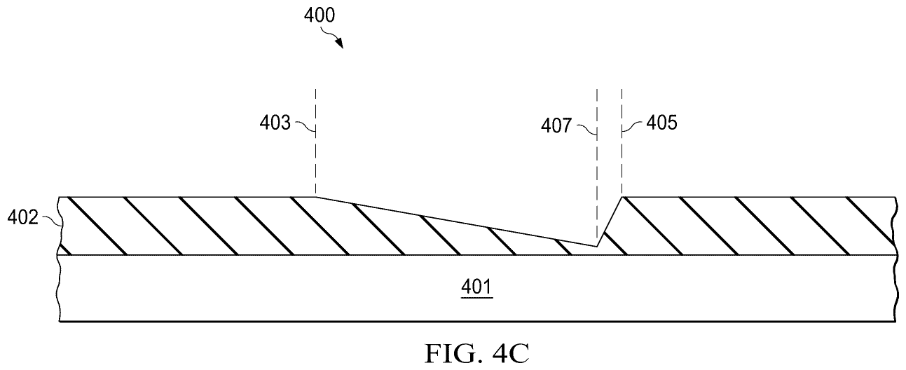

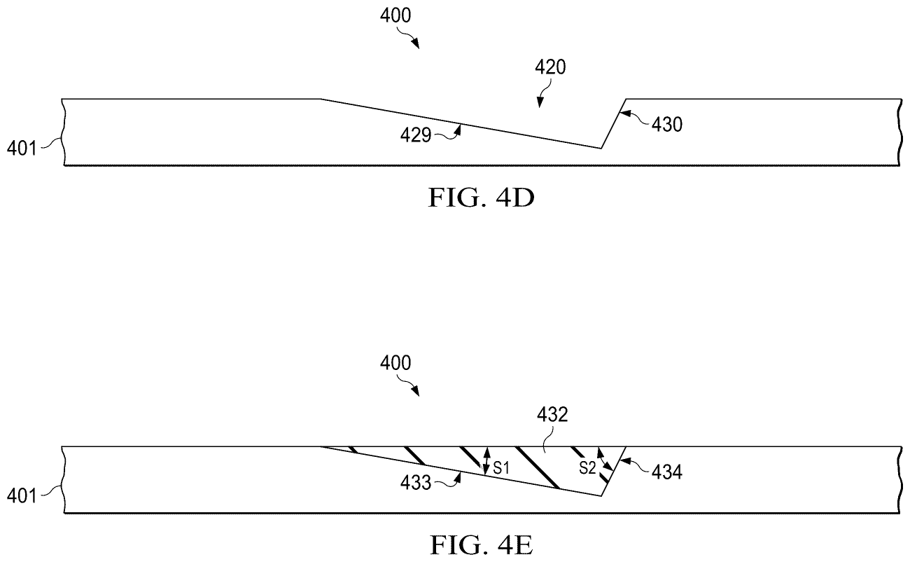

In other examples (e.g., the process flow of FIGS. 4A-4E), photolithographic mask devices (e.g., masks, photomasks, reticles) are used to form trenches for asymmetric graded STI layers. A form of photolithography, referred to as grayscale photolithography, facilitates three-dimensional (3D) structure shaping, e.g., structures defined in x and y dimensions on a plane with non-perpendicular (e.g., sloped, tapered, contoured) sidewall profiles.

More particularly, grayscale mask-based lithography uses a mask device (e.g., sometimes referred to as a grayscale mask or grayscale reticle) to spatially modulate or modify the light intensity or dosage applied to a photoresist layer formed on an underlying layer of the device being fabricated. By way of example, the light applied to the grayscale mask device typically is ultra-violet (UV) light. Modulation of the light is enabled by a patterned opaque layer disposed on a light-passing substrate. The patterned opaque layer includes areas of opaque material (opaque areas of the patterned opaque layer) and areas without opaque material (open areas of the patterned opaque layer where a surface of the light-passing substrate is exposed). For example, the opaque areas can be composed of a metal material such as, but not limited to, chrome, chromium, and/or a metal oxide. The light-passing substrate can be composed of a light-passing material such as, but not limited to, quartz, fused silica, and/or glass. Thus, in one example, a grayscale mask device can be fabricated where chrome serves as the opaque material and glass serves as the light-passing material. Such a mask device is sometimes referred to as a chrome-on-glass (COG) mask. In general, such a mask can also be referred to as a binary mask given its functionality to block light in certain areas and pass light in other areas.

During the grayscale photolithographic process, the applied light is blocked or obstructed by opaque areas of the patterned opaque layer while passing through the open areas and then through the substrate. More particularly, grayscale mask devices rely on the concept of diffraction where light bends or spreads around the edges of the opaque areas while passing through the open areas of the patterned opaque layer.

Accordingly, the term “opaque,” as illustratively used herein, refers to a characteristic of a material to block applied light by reflection, absorption, and/or some other light-blocking functionality. The term “light-passing,” as illustratively used herein, refers to a characteristic of a material to enable all or most of the applied light to pass (e.g., transparent material) or some portion of the applied light to pass (e.g., translucent or semitransparent material).

In a clear field mask, the pattern features formed in the patterned opaque layer on a surface of the light-passing substrate are composed of opaque material and thus block light, while clear or open areas (lack of opaque material) expose the surface of the light-passing substrate and thus pass light. In contrast, in a dark field mask, the pattern features on the surface are clear or open areas (pass light) while the other areas on the surface are opaque material and thus block light. Depending on the structures being fabricated in the underlying device, either type of mask device (clear field or dark field) can be used with a positive photoresist material or a negative photoresist material.

The modulated light passing through the mask device, e.g., measured as an intensity-pass percentage, correspondingly modulates or modifies the amount of photosensitive material that is removed (positive photoresist) or remains (negative photoresist) in the photoresist layer to form a profile in the photoresist layer. Thus, in a positive photoresist example, the more light that passes through the mask device (e.g., higher intensity-pass percentage) onto the photoresist layer, the more photosensitive material of the photoresist layer is removed during development (e.g., decreasing the thickness of the photoresist layer from its original thickness). Thus, by modulating the applied light to change the exposure dose or intensity locally in the photoresist layer, profiles can be selectively formed in the photoresist layer, e.g., non-perpendicular photoresist sidewall profiles. The profiles can then be transferred to the underlying layer of the semiconductor device to fabricate various structures of the semiconductor device, such as trenches for asymmetric graded STI layers.

Process flows for forming asymmetric graded field relief dielectric layers, e.g., asymmetric graded STI layers 118 and 168 shown in FIGS. 1A and 1B, will now be described with respect to FIGS. 2A-4E.

FIG. 2A shows a cross-sectional view of structures 200 and 250, which include semiconductor layers 201 and 251, padding layers 202 and 252, first hard mask layers 203 and 253, second hard mask layers 204 and 254, and photoresist layers 205 and 255. The structure 200 may be used for forming a relatively LV LDMOS device (e.g., LDMOS device 100 of FIG. 1A), while the structure 250 may be used for forming a relatively HV LDMOS device (e.g., LDMOS device 150 of FIG. 1B). In examples, the LV and HV LDMOS devices can be formed at the same (or substantially the same) time in different portions of a structure, where the semiconductor layers 201 and 251, the padding layers 202 and 252, the first hard mask layers 203 and 253, and the second hard mask layers 204 and 254 are the same. The photoresist layers 205 and 255 are formed in different areas for defining the steep edge of asymmetric graded field relief dielectric layers for the LV and HV LDMOS devices.

The semiconductor layers 201 and 251 may be formed of silicon (Si) or another suitable semiconductor material. In examples, the semiconductor layers 201 and 251 are formed using an epitaxial growth process and are thus referred to as epitaxial or “epi” layers 201 and 251.

The padding layers 202 and 252 may be formed of an oxide or other suitable material. The padding layers 202 and 252 are blanket deposited over the epi layers 201 and 251 or thermally grown on the epi layers 201 and 251—e.g., using an oxidation process. The padding layers 202 and 252 may have a thickness in the range of, for example, 50-150 angstroms (Å).

The first hard mask layers 203 and 253 may be formed of a nitride material, and may be referred to as nitride hard mask layers 203 and 253. The nitride hard mask layers 203 and 253 are blanket deposited over the padding layers 202 and 252. The nitride hard mask layers 203 and 253 have a thickness which is sufficient for transferring a trench pattern of a desired depth for the asymmetric graded STI layers. In some examples, the nitride hard mask layers 203 and 253 have a thickness that is similar to the desired thickness of the asymmetric graded STI layers that are to be formed in the structures 200 and 250, so that the transfer etch (e.g., from the nitride hard mask layers 203 and 253 to the epi layers 201 and 251) may utilize a non-selective plasma etch process. In other examples, the nitride hard mask layers 203 and 253 may be thicker or thinner than the desired thickness of the asymmetric graded STI layers which are to be formed in the structures 200 and 250, if the plasma etch process selectivity is modified.

The second hard mask layers 204 and 254 may be formed of an oxide material, and may be referred to as oxide hard mask layers 204 and 254. The oxide hard mask layers 204 and 254 are blanket deposited over the nitride hard mask layers 203 and 253. The oxide hard mask layers 204 and 254 may have a thickness of approximately 50 nanometers (nm).

The photoresist layers 205 and 255 may be formed of a photoresist material. The photoresist layers 205 and 255 are patterned to define the steep edge of the trench for the asymmetric graded STI layers which are to be formed in the structures 200 and 250. The photoresist layers 205 and 255 are patterned over the oxide hard mask layers 204 and 254 using lithographic processing.

FIG. 2B shows a cross-sectional view of the structures of FIG. 2A following etching portions of the oxide hard mask layers 204 and 254 which are exposed by the photoresist layers 205 and 255.

FIG. 2C shows a cross-sectional view of the structures of FIG. 2B following removal of the photoresist layers 205 and 255.

FIG. 2D shows a cross-sectional view of the structures of FIG. 2C following formation of patterning layers 206 and 256 over the structure, and following patterning of photoresist layers 207 and 257 over the patterning layers 206 and 256. In some examples, the patterning layers 206 and 256 are formed of an organic bottom anti-reflective coating (BARC) material, and thus may be referred to as organic BARC layers 206 and 256. In other examples, the patterning layers 206 and 256 are multi-layer resist (MLR) organic hard masks. The organic BARC layers 206 and 256 have a thickness that is sufficient to surround and cover the top surface of the oxide hard mask layers 204 and 254, to ensure that subsequent etch and trim processing does not run out of mask material.

The edge of the photoresist layers 207 and 257 proximate to the oxide hard mask layers 204 and 254 defines the deep side of the shallow edge of the asymmetric graded STI layers which are to be formed in the structures 200 and 250. The distance between the edge of the photoresist layers 207 and 257 and the edge of the oxide hard mask layers 204 and 254 defines the non-sloped portion of the asymmetric graded STI layers which are to be formed in the structures 200 and 250. As illustrated in FIG. 2D, there is a greater distance between the edge of the photoresist layer 257 and the edge of the oxide hard mask layer 254 (e.g., for forming an asymmetric graded STI layer for a relatively HV LDMOS device) than between the edge of the photoresist layer 207 and the edge of the oxide hard mask layer 204 (e.g., for forming an asymmetric graded STI layer for a relatively LV LDMOS device).

In some examples, there can be about 14 nm alignment capability to the steep edge when using 248 nm lithographic processing—e.g., for aligning the edges of the photoresist layers 207 and 257 with respect to the oxide hard mask layers 204 and 254, respectively. The 248 nm lithographic processing with 3950 Å thick resist may provide sufficient thickness for trimming (e.g., trim range) described in subsequent steps. The photoresist layers 207 and 257 have a depth, e.g., a dimension into the page, and trimming occurs uniformly throughout the depth. Further, corners of the trench may become round on the shallow edge, with three of the four sides of the trench being confined by the steep edge pattern. The slope of the shallow sloped region of the asymmetric graded STI layers that are to be formed may be determined by the desired length of the LV devices—e.g., as a result of tuning the trim-and-etch processing described below (tuning of nitride etch and trim etch durations).

FIG. 2E shows a cross-sectional view of the structures of FIG. 2D following etching of the organic BARC layers 206 and 256, e.g., using a dry etch or other suitable processing. This etching of the organic BARC layers 206 and 256 exposes a portion of the top surface of the nitride hard mask layers 203 and 253.

FIG. 2F shows a cross-sectional view of the structures of FIG. 2E following a partial etching of the exposed portion of the nitride hard mask layers 203 and 253. Moreover, the thickness of the oxide hard mask layers 204 and 254 may be reduced as a result of partially etching the nitride hard mask layers 203 and 253. This etching may utilize a short nitride dry etch, with a selectivity requirement defined by a ratio of the thickness of the oxide hard mask layers 204 and 254 and the thickness of the nitride hard mask layers 203 and 253. The depth of the partial etching of the exposed portion of the nitride hard mask layers 203 and 253 may be a designated percentage of the thickness of the nitride hard mask layers 203 and 253 which will be based on the number of trim-and-etch cycles that are utilized. In some examples, the designated percentage is 5-33% of the thickness of the nitride hard mask layers 203 and 253.

FIG. 2G shows a cross-sectional view of the structures of FIG. 2F following a trim of the photoresist layers 207 and 257 and the organic BARC layers 206 and 256. The trim may be an O₂-based trim cycle, which trims the edge of the photoresist layers 207 and 257 and the organic BARC layers 206 and 256 away from the edge of the oxide hard mask layers 204 and 254 by respective length dimensions T1 and T2. T1 and T2 are defined by the dimensions needed for different devices (e.g., LV and HV LDMOS devices). In some examples, T2 can be up to 500 nm longer than T1. Moreover, the thickness of the oxide hard mask layers 204 and 254 may be further reduced as a result of the trimming.

FIG. 2H shows a cross-sectional view of the structures of FIG. 2G following another partial etching of the exposed portion of the nitride hard mask layers 203 and 253. This partial etching may utilize repeated nitride etch cycles, which rounds the exposed corners of the nitride hard mask layers 203 and 253 due to natural etch faceting—e.g., due to increased interactions with etchants and/or etching species at the corners. The depth of the partial etching shown in FIG. 2H may be similar to the depth of the partial etching shown in FIG. 2F, though greater amounts of the nitride hard mask layers 203 and 253 are exposed due to the trim of the photoresist layers 207 and 257 and the organic BARC layers 206 and 256 shown in FIG. 2G. This partial etching may also consume or remove a portion of the photoresist layers 207 and 257 and the oxide hard mask layers 204 and 254, depending on the selectivity of the etch process.

FIG. 2I shows a cross-sectional view of the structures of FIG. 2H following repeated cycles or iterations of the trim-and-etch processing described above with respect to FIGS. 2G and 2H. The trim-and-etch processing is iterated until the nitride hard mask layers 203 and 253 are completely etched through. FIG. 2I also illustrates remaining portions of the photoresist layers 207 and 257 as well as remaining portions of the oxide hard mask layers 204 and 254 at this stage. The number of iterating the trim-and-etch processing cycles or the trim and nitride etch times per cycle may be tuned to achieve a desired profile, e.g., a staircase-like profile, an overall slope (or steepness) of the staircase-like profile. The total mask height requirements (e.g., thickness of the organic BARC layers 206 and 256, thickness of the oxide hard mask layers 204 and 254) may be determined by the total lateral trim amount and the total amount of the oxide hard mask layers 204 and 254 consumed during the nitride etch.

FIG. 2J shows a cross-sectional view of the structures of FIG. 2I following removal of remaining portions of the photoresist layers 207 and 257 and the organic BARC layers 206 and 256.

FIG. 2K shows a cross-sectional view of the structures of FIG. 2J following transfer of the profile of the nitride hard mask layers 203 and 253 into the underlying epi layers 201 and 251—e.g., by utilizing a plasma etch process. The transfer results in a trench 208 being formed having a first (shallow) trench sidewall 209, a second (steep) trench sidewall 210, and a trench bottom 211 in structure 200, and a trench 258 being formed having a first (shallow) trench sidewall 259, a second (steep) trench sidewall 260, and a trench bottom 261 in structure 250. Further, the transfer provides another opportunity to tune or smooth the staircase-like profile, though any such tuning will impact the sidewalls (e.g., shallow trench sidewall, steep trench sidewall) of the respective trenches 208 and 258. Still further, in some examples, a relatively greater area of the shallow edge pattern in comparison to a relatively lesser area of the steep edge pattern may facilitate detecting etch endpoints during the transfer etch process where the etch endpoints that are detected are the clearing of the nitride hard mask layers 203 and 253.

FIG. 2L shows a cross-sectional view of the structures of FIG. 2K following formation of asymmetric graded STI layers 212 and 262 in the trenches 208 and 258 of the epi layers 201 and 251. The formation results in a first (shallow) layer sidewall 213, a second (steep) layer sidewall 214, and a layer bottom 215 of asymmetric graded STI layer 212, and a first (shallow) layer sidewall 263, a second (steep) layer sidewall 264, and a layer bottom 265 of asymmetric graded STI layer 262. The asymmetric graded STI layers 212 and 262 may be formed using an ISSG process that grows an oxide layer on the surface of the semiconductor layers 201 and 251 in the trenches, which may further round corners of the trenches. Subsequently, the trenches are filled with a dielectric material (e.g., oxide material) and planarized, e.g., using chemical mechanical polishing (CMP). As a result of the CMP process, the asymmetric graded STI layers 212 and 262 are flush with the top surface of the padding layers 202 and 252. In some examples, following the above-described tuning, smoothing, and/or rounding, the resulting sidewalls of asymmetric graded STI layers 212 and 262 may retain, albeit reduced, some staircase-like or scalloped contour. FIG. 2L shows, in exploded view 270, a detailed view of a portion of the first (shallow) layer sidewall 263 of the asymmetric graded STI layer 262, illustrating how the staircase-like or scalloped contour of the nitride hard mask layer 253 is at least partially retained, in some examples, during the transfer of the profile utilizing the plasma etch process. The first (shallow) layer sidewall 213 of the asymmetric graded STI layer 212, in some examples, similarly at least partially retains the staircase-like or scalloped contour of the nitride hard mask layer 203, such that the contour of the first (shallow) layer sidewall 263 of the asymmetric graded STI layer 262 shown in the exploded view 270 is representative of the contour of first (shallow) layer sidewall 213 of the asymmetric graded STI layer 212.

The process flow shown in FIGS. 2A-2L involves no overlap of the first mask (e.g., the photoresist layers 205 and 255) and the second mask (e.g., the photoresist layers 207 and 257). Scaling the devices for varying voltages may be achieved through lateral scaling of the flat or non-sloped portions of the asymmetric graded STI layers 212 and 262 (e.g., through controlling a distance between the edges of the photoresist layers 207 and 257 and the edges of the oxide hard mask layers 204 and 254). The slope and depth of the shallow sidewalls of the asymmetric graded STI layers 212 and 262 may be substantially the same—e.g., as a result of the trenches being concurrently formed as described above. Similarly, the slope and depth of the steep sidewalls of the asymmetric graded STI layers 212 and 262 may be substantially the same. In some examples, however, respective shallow slopes between devices and/or respective steep slopes between devices may differ—e.g., respective trenches being formed separately pursuant to respective desirable electrical characteristics between the devices.

Thus, by way of example as shown in FIG. 2L, a depth dimension D1 is equal for both asymmetric graded STI layers 212 and 262. Further, shallow slope dimension S1 (e.g., a length of the shallow sidewall portion in a direction of current flow between the source and drain regions, an angle of the shallow sidewall portion with respect to the layer bottom 215, 265) is equal for both asymmetric graded STI layers 212 and 262, as is steep slope dimension S2 (e.g., a length of the steep sidewall portion in a direction of current flow between the source and drain regions, an angle of the steep sidewall portion with respect to the layer bottom 215, 265). However, lateral scaling between asymmetric graded STI layers 212 and 262 is shown in FIG. 2L where a lateral dimension L1 of asymmetric graded STI layer 212 is less than a lateral dimension L2 of asymmetric graded STI layer 262—e.g., based on the different distances between the edges of the photoresist layers 207 and 257 and the edges of the oxide hard mask layers 204 and 254, respectively.

FIG. 3A shows a cross-sectional view of structures 300 and 350, which include semiconductor layers 301 and 351, padding layers 302 and 352, first hard mask layers 303 and 353 (also referred to herein as nitride hard mask layers 303 and 353), second hard mask layers 304 and 354 (also referred to herein as oxide hard mask layers 304 and 354), and photoresist layers 305 and 355. In examples, the semiconductor layers 301 and 351 are formed using an epitaxial growth process and are thus referred to as epitaxial or “epi” layers 301 and 351. The structure 300 may be used for forming a relatively LV LDMOS device (e.g., LDMOS device 100 of FIG. 1A), while the structure 350 may be used for forming a relatively HV LDMOS device (e.g., LDMOS device 150 of FIG. 1B). In examples, the LV and HV LDMOS devices can be formed at the same time in different portions of a structure, where the epi layers 301 and 351, the padding layers 302 and 352, the first hard mask layers 303 and 353, and the second hard mask layers 304 and 354 are the same. Further, the photoresist layers 305 and 355 are formed in different areas for defining the steep edge of asymmetric graded field relief dielectric layers for the LV and HV LDMOS devices. While in the process flow of FIGS. 2A-2L the photoresist layers 205 and 255 have the same length, in the process flow of FIGS. 3A-3L the photoresist layer 305 is longer than the photoresist layer 355. This results in mask overlap, which enables scaling of depth and length for LV and HV LDMOS devices.

When compared to the photoresist layer 205 of FIG. 2A, the photoresist layer 305 of FIG. 3A is longer than the photoresist layer 205 such that the later-formed second hard mask layer 304 overlaps with the later-formed photoresist layer 307 as illustrated in FIG. 3D. Such an overlap enables scaling of depth and length for LV LDMOS devices when compared to HV LDMOS devices. For example, a thickness of a field relief dielectric layer of a LV LDMOS device may be less than a thickness of a field relief dielectric layer of a HV LDMOS device. Similarly, a length of a shallow-sloped sidewall of a field relief dielectric layer of a LV LDMOS device may be less than a length of a shallow-sloped sidewall of a field relief dielectric layer of a HV LDMOS device.

The epi layers 301 and 351, the padding layers 302 and 352, the first hard mask layers 303 and 353, the second hard mask layers 304 and 354 and the photoresist layers 305 and 355 may be formed of similar materials and with similar processing as that described above with respect to the epi layers 201 and 251, the padding layers 202 and 252, the first hard mask layers 203 and 253, the second hard mask layers 204 and 254 and the photoresist layers 205 and 255, respectively.

FIG. 3B shows a cross-sectional view of the structures of FIG. 3A following etching portions of the oxide hard mask layers 304 and 354 which are exposed by the photoresist layers 305 and 355.

FIG. 3C shows a cross-sectional view of the structures of FIG. 3B following removal of the photoresist layers 305 and 355.

FIG. 3D shows a cross-sectional view of the structures of FIG. 3C following formation of patterning layers 306 and 356 over the structure, and following patterning of photoresist layers 307 and 357 over the patterning layers 306 and 356. The patterning layers 306 and 356 and the photoresist layers 307 and 357 may be formed of similar materials as the patterning layers 206 and 256 and the photoresist layers 207 and 257, respectively. In some examples, the patterning layers 306 and 356 are formed of an organic BARC material and are referred to as organic BARC layers 306 and 356. The organic BARC layers 306 and 356 have a thickness that is sufficient to surround and cover the top surface of the oxide hard mask layers 304 and 354, to ensure that subsequent etch and trim processing does not run out of mask material.

The edge of the oxide hard mask layer 304 substantially defines the deep side of the shallow edge of the asymmetric graded STI layer to be formed in the structure 300 as shown in FIGS. 31 through 3L. The edge of the photoresist layer 357 proximate to the oxide hard mask layer 354 substantially defines the deep side of the shallow edge of the asymmetric graded STI layers to be formed in the structure 350 as shown in FIGS. 31 through 3L. As shown in FIG. 3D, the photoresist layer 357 is spaced apart from the edge of the oxide hard mask layer 354, while the photoresist layer 307 overlaps the edge of the second hard mask layer 304 such that the photoresist layer 307 (e.g., the second mask) overlaps the steep edge pattern defined by the photoresist layer 305 (e.g., the first mask). Such an overlap (or lack thereof) will result in different depths and lengths for different devices. For example, a depth of an asymmetric trench of a LV LDMOS device may be less than a depth of an asymmetric trench of a HV LDMOS device. Similarly, a length of a shallow-sloped sidewall of the trench of the LV LDMOS device may be less than a length of a shallow-sloped sidewall of the trench of a HV LDMOS device. The shallow slope (e.g., overall steepness of a shallow-sloped sidewall) may be substantially the same for the different devices (e.g., for the LV LDMOS device and the HV LDMOS device).

In some examples, there may be about 14 nm alignment capability to the steep edge when using 248 nm lithographic processing—e.g., for aligning the edges of the photoresist layers 307 and 357 with respect to the oxide hard mask layers 304 and 354, respectively. The 248 nm lithographic processing with 3950 Å thick resist may provide sufficient thickness for trimming (e.g., trim range) described in subsequent steps. The photoresist layers 307 and 357 also have a depth, e.g., a dimension into the page, and trimming occurs uniformly throughout the depth. Further, corners of the trench may become round on the shallow edge, with three of the four sides of the trench being confined by the steep edge pattern. The slope of the shallow sloped region of the asymmetric graded STI layers that are to be formed may be determined by the desired length of the LV devices—e.g., as a result of tuning the trim-and-etch processing described below (tuning of nitride etch and trim etch durations).

FIG. 3E shows a cross-sectional view of the structures of FIG. 3D following etching of the organic BARC layers 306 and 356, e.g., using a dry etch or other suitable processing. This etching of the organic BARC layer 306 exposes a portion of the top surface of the oxide hard mask layer 304, and the etching of the organic BARC layer 356 exposes a portion of the top surface of the nitride hard mask layer 353.

FIG. 3F shows a cross-sectional view of the structures of FIG. 3E following a partial etching of the exposed portion of the nitride hard mask layer 353. Moreover, the thickness of the oxide hard mask layer 354 may be reduced as a result of partially etching the nitride hard mask layers 353. This etching may utilize a short nitride dry etch, with a selectivity requirement defined by a ratio of the thickness of the oxide hard mask layer 354 and the thickness of the nitride hard mask layer 353. A depth of the partial etching of the exposed portion of the nitride hard mask layer 353 may be a designated percentage of the thickness of the nitride hard mask layer 353 which will be based on the number of trim-and-etch cycles that are utilized and a desired thickness of the asymmetric STI layer that will be formed in the structure 350 (e.g., the depth dimension D2 discussed in detail below with respect to FIG. 3L). In some examples, the designated percentage is 5-33% of the thickness of the nitride hard mask layer 353. In the structure 300, the nitride hard mask layer 303 is still covered by the oxide hard mask layer 304, and thus the nitride hard mask layer 303 is not etched.

FIG. 3G shows a cross-sectional view of the structures of FIG. 3F following a trim of the photoresist layers 307 and 357 and the organic BARC layers 306 and 356. The trim may be an O₂-based trim cycle, which trims the edge of the photoresist layer 307 and the organic BARC layers 306 over the oxide hard mask layer 304 by a length dimension of T1, and trims the edge of the photoresist layer 357 and the organic BARC layers 356 away from the oxide hard mask layer 354 by a length dimension of T2. T1 and T2 are defined by the dimensions needed for different devices (e.g., LV and HV LDMOS devices). In some examples, T2 may be up to 500 nm longer than T1. Moreover, the thickness of the oxide hard mask layer 304, exposed before the trimming, may be further reduced as a result of the trimming.

FIG. 3H shows a cross-sectional view of the structures of FIG. 3G following a partial etching of the exposed portion of the nitride hard mask layer 353. This partial etching may utilize repeated nitride etch cycles, which rounds the exposed corner of the nitride hard mask layer 353 due to natural etch faceting—e.g., due to increased interactions with etchants and/or etching species at the corners. The depth of the partial etching shown in FIG. 3H may be similar to the depth of the partial etching shown in FIG. 3F, though a greater amount of the nitride hard mask layer 353 is exposed due to the trim of the photoresist layer 357 and the organic BARC layer 356 shown in FIG. 3G. This partial etching may also consume or remove a portion of the photoresist layers 307 and 357 and the oxide hard mask layers 304 and 354, depending on the selectivity of the etch process.

FIG. 3I shows a cross-sectional view of the structures of FIG. 3H following repeated cycles or iterations of the trim-and-etch processing described above with respect to FIGS. 3G and 3H. At a certain trim amount, the nitride hard mask layer 303 is exposed along with the nitride hard mask layer 353, and the trim-and-etch processing is iterated until the nitride hard mask layer 353 is completely etched through. Due to the overlap of the first and second masks in the structure 300, the nitride hard mask layer 303 is not completely etched through. FIG. 3I also illustrates remaining portions of the photoresist layers 307 and 357 as well as remaining portions of the oxide hard mask layers 304 and 354 at this stage. The number of iterating the trim-and-etch processing cycles or the trim and nitride etch times per cycle may be tuned to achieve a desired profile, e.g., a staircase-like profile, an overall slope (or steepness) of the staircase-like profile. The trim and nitride etch times are tuned to achieve a desired profile, e.g., a staircase-like profile. The total mask height requirements (e.g., thickness of the organic BARC layers 306 and 356, thickness of the oxide hard mask layers 304 and 354) may be determined by the total lateral trim amount and the total amount of the oxide hard mask layers 304 and 354 consumed during the nitride etch.

FIG. 3J shows a cross-sectional view of the structures of FIG. 3I following removal of remaining portions of the photoresist layers 307 and 357 and the organic BARC layers 306 and 356.

FIG. 3K shows a cross-sectional view of the structures of FIG. 3J following transfer of the profile of the nitride hard mask layers 303 and 353 into the underlying epi layers 301 and 351—e.g., by utilizing a plasma etch process. The transfer results in a trench 308 being formed having a first (shallow) trench sidewall 309 and a second (steep) trench sidewall 310 in structure 300, and a trench 358 being formed having a first (shallow) trench sidewall 359, a second (steep) trench sidewall 360, and a trench bottom 361 in structure 350. Further, the transfer provides another opportunity to tune or smooth the staircase-like profile, though any such tuning will impact the sidewalls (e.g., shallow trench sidewall, steep trench sidewall) of the respective trenches 308 and 358. Still further, in some examples, a relatively greater area of the shallow edge pattern in comparison to a relatively lesser area of the steep edge pattern may facilitate detecting etch endpoints during the transfer etch process where the etch endpoints that are detected are the clearing of the nitride hard mask layers 303 and 353.

FIG. 3L shows a cross-sectional view of the structures of FIG. 3K following formation of asymmetric graded STI layers 312 and 362 in the trenches 308 and 358 of the epi layers 301 and 351. The formation results in a first (shallow) layer sidewall 313 and a second (steep) layer sidewall 314 of asymmetric graded STI layer 312, and a first (shallow) layer sidewall 363, a second (steep) layer sidewall 364, and a layer bottom 365 of asymmetric graded STI layer 362. The asymmetric graded STI layers 312 and 362 may be formed using an ISSG process that grows an oxide layer on the surface of the semiconductor layers 301 and 351 in the trenches, which may further round corners of the trenches. Subsequently, the trenches are filled with a dielectric material (e.g., oxide material) and planarized, e.g., using chemical mechanical polishing (CMP). As a result of the CMP process, the asymmetric graded STI layers 312 and 362 are flush with the top surface of the padding layers 302 and 352. In some examples, following the above-described tuning, smoothing, and/or rounding, the resulting sidewalls of asymmetric graded STI layers 312 and 362 may retain, albeit reduced, some staircase-like or scalloped contour. FIG. 3L shows, in exploded view 370, a detailed view of a portion of the first (shallow) layer sidewall 363 of the asymmetric graded STI layer 362, illustrating how the staircase-like or scalloped contour of the nitride hard mask layer 353 is at least partially retained, in some examples, during the transfer of the profile utilizing the plasma etch process. The first (shallow) layer sidewall 313 of the asymmetric graded STI layer 312, in some examples, similarly at least partially retains the staircase-like or scalloped contour of the nitride hard mask layer 303, such that the contour of the first (shallow) layer sidewall 363 of the asymmetric graded STI layer 362 shown in the exploded view 370 is representative of the contour of first (shallow) layer sidewall 313 of the asymmetric graded STI layer 312.

In the processing flow of FIGS. 3A-3L, the overlap of the pattern for the shallow-sloped edge and the steep edge provides a technique for scaling the depth of the trenches for the asymmetric graded STI layers 312 and 362 for different voltage devices (e.g., LV and HV LDMOS devices). The slopes will be substantially the same between the devices for both the shallow and the steep side—e.g., as a result of the trenches being concurrently formed as described above, but the trenches will vary by length and depth based on the amount of overlap in the patterning. In some examples, however, respective shallow slopes between devices and/or respective steep slopes between devices may differ—e.g., respective trenches being formed separately pursuant to respective desirable electrical characteristics between the devices.

Thus, by way of example and based on the above-described processing, lateral scaling between asymmetric graded STI layers 312 and 362 is shown in FIG. 3L where a lateral dimension L1 of asymmetric graded STI layer 312 is less than a lateral dimension L2 of asymmetric graded STI layer 362. Further, by way of example and based on the above-described processing, depth scaling between asymmetric graded STI layers 312 and 362 is shown in FIG. 3L where a depth dimension D1 of asymmetric graded STI layer 312 is less than a depth dimension D2 of asymmetric graded STI layer 362. Still further, shallow slope dimension S1 is substantially equal for both asymmetric graded STI layers 312 and 362, as is steep slope dimension S2. Slopes S1 and S2 may be measured similarly to slopes S1 and S2 described above in the context of FIG. 2L.

FIG. 4A shows a cross-sectional view of a structure 400 including a semiconductor layer 401 and a photoresist layer 402 that is blanket deposited over the semiconductor layer 401. The semiconductor layer 401 may be formed of silicon (Si) or another suitable semiconductor material. In examples, the semiconductor layer 401 is formed using an epitaxial growth process and is thus referred to as epitaxial or “epi” layer 401. FIG. 4A also shows a dashed line 403 illustrating where the source-side edge of an asymmetric graded STI layer will be formed, a dashed line 405 illustrating where the drain-side edge of the asymmetric graded STI layer will be formed, and a dashed line 407 illustrating where the sloped sidewalls (e.g., the shallow-sloped sidewall that extends toward a source region and the steep-sloped sidewall that extends toward a drain region) will meet.

FIG. 4B shows a cross-sectional view where the structure 400 is subject to grayscale mask-based lithographic processing using a mask device 408. As shown, mask device 408 is placed over the structure 400 and includes a light-passing substrate 409 with a first non-modulating region 411, a modulating region 413, and a second non-modulating region 415 formed on the light-passing substrate 409. A light source 417 is positioned over the mask device 408. The first non-modulating region 411 and the second non-modulating region 415 are areas where the photoresist layer 402 will not be removed. The modulating region 413 includes sets of features, where at least a subset of the set of features are disposed at differing distances from one another for defining the shallow-sloped and steep-sloped sidewalls as defined by the dashed lines 403, 405 and 407. In examples where there is a non-sloped or flat portion between the shallow-sloped and steep-sloped sidewalls, this may also be defined utilizing the modulating region 413 or based on another non-modulating region (not expressly shown) appropriately positioned between dashed lines 403 and 407.

FIG. 4C shows a cross-sectional view of the structure 400 following the grayscale mask-based lithographic process, where the photoresist layer 402 is patterned with a trench having the desired shape for an asymmetric graded STI layer that is to be formed.

FIG. 4D shows a cross-sectional view of the structure 400 following transfer of the profile of the photoresist layer 402 into the underlying epi layer 401—e.g., based on an etch process. The transfer results in a trench 420 being formed having a first (shallow) trench sidewall 429 and a second (steep) trench sidewall 430 in structure 400.

FIG. 4E shows a cross-sectional view of the structure 400 following formation of asymmetric graded STI layer 432 in the trench 420 of the epi layer 401. The formation results in a first layer sidewall 433 (shallow, e.g., slope dimension S1) and a second layer sidewall 434 (steep, e.g., slope dimension S2) of the asymmetric graded STI layer 432. The asymmetric graded STI layer 432 may be formed using an ISSG process which rounds corners of the trenches, followed by fill of a dielectric material for the asymmetric graded STI layer 432 and planarization, e.g., using CMP, of the dielectric material such that asymmetric graded STI layer 432 is flush with the top surface of the epi layer 401.

The structures shown in FIGS. 2L, 3L and 4E may be subject to further processing to form LDMOS devices. Such additional processing includes forming source well regions, source regions, drain drift regions, drain regions, gate insulators, gates, silicide layers, an ILD, conductive vias, etc.

The processing steps for forming the asymmetric graded STI layers 212, 262, 312, 362 and 432 shown in FIGS. 2L, 3L and 4E (which may be referred to as an asymmetric graded STI process module hereinafter) may be integrated with other processing steps to form additional portions of an LDMOS device to result in one of the LDMOS devices 100 and 150 described above. In some examples, the asymmetric graded STI process module may be added prior to formation of processing steps for, e.g., forming a drain drift region (e.g., drain drift region 116 or drain drift region 166), forming a well region (e.g., well region 112 or well region 162), forming a gate insulator (e.g., gate insulator 120 or gate insulator 170), forming a gate (e.g., gate 122 or gate 172), forming gate spacers (not specifically shown), forming a source region (e.g., source region 110 or source region 160) and a drain region (e.g., drain region 114 or drain region 164), forming silicide layers (e.g., silicide layers 124, 126 and 128 or silicide layers 174, 176 and 178), forming an ILD (e.g., ILD 130 or ILD 180) and forming conductive vias (e.g., conductive vias 132, 134 and 136 or conductive vias 182, 184 and 186).

In other examples, the asymmetric graded STI process module may be added after implants forming various drift and well regions in the semiconductor layer (e.g., epi layer 108 or epi layer 158), prior to forming a gate insulator (e.g., gate insulator 120 or gate insulator 170) and a gate (e.g., gate 122 or gate 172) on the gate insulator. After forming the gate stack including the gate insulator and the gate, additional process steps may be performed, e.g., forming gate spacers (not specifically shown), forming a source region (e.g., source region 110 or source region 160) and a drain region (e.g., drain region 114 or drain region 164), forming silicide layers (e.g., silicide layers 124, 126 and 128 or silicide layers 174, 176 and 178), forming an ILD (e.g., ILD 130 or ILD 180) and forming conductive vias (e.g., conductive vias 132, 134 and 136 or conductive vias 182, 184 and 186). Certain aspects of process flows for forming such additional portions will now be described.

In some examples, a drain drift region (e.g., drain drift region 116 or drain drift region 166) is formed in a semiconductor layer (e.g., epi layer 108 or epi layer 158) by performing one or more masked implantation steps, e.g., by forming a drain drift mask layer (or a photomask). In some examples, an implant to form the drain drift region occurs in two steps (e.g., a first implantation process with a first energy and a first dose followed by a second implantation process with a second energy and a second dose). In some examples, the first implantation process implants phosphorous dopants at the first energy of 20-40 kilo-electron volts (keV) and the first dose of 2-8×10¹² cm⁻². In some examples, the first implantation process implants phosphorus dopants at the first energy of 20-40 keV for an oxide thickness of 70-110 nm. In some examples, the first dose is 2-5×10¹² cm⁻². The second implantation process uses the same drain drift mask layer to implant the same region of the semiconductor layer. In some examples, the second energy is greater than the first energy. In some examples, the second implantation process implants phosphorus dopants at the second energy of 70-350 keV and the second dose of 2-5×10¹² cm⁻². In some examples, the second implantation process implants phosphorus dopants at the second energy less than or equal to 150 keV. In some examples, the second implantation process implants phosphorus dopants at the second energy greater than or equal to 100 keV, such as 100-350 keV. In some examples, the second implantation process includes more than one implant, such as an implantation at 120 keV and another implantation at 250 keV.

Following formation of the drain drift region, the drain drift mask layer is removed and a well region mask layer is patterned over the semiconductor layer to expose portions of the semiconductor layer where the well region (e.g., well region 112 or well region 162) is to be formed. An implantation process is then performed to implant p-type dopants within the exposed areas of the semiconductor layer to form the well region. The p-type dopants may include boron. Besides boron, the p-type dopants can include indium. Indium, being a relatively large atom, has the advantage of a low diffusion coefficient relative to boron. In the case of a boron implant, the implantation process uses a dose sufficient to enable formation of a channel laterally and to suppress body NPN effects during operation of an LDMOS device. For example, a boron implant with an energy of 20 keV, a dose of 8×10¹³ cm⁻² to 3.0×10¹⁴ cm⁻², such as 1.5×10¹⁴ cm², and a tilt angle of less than 5 degrees, such as 2 degrees, may be used. The well region mask layer may then be removed after the implantation process.

The gate insulator (e.g., gate insulator 120 or gate insulator 170) and the gate (e.g., gate 122 or gate 172) may be formed over the structure through deposition and patterning using one or more gate masking layers. In some examples, a gate insulator material is formed using a high temperature furnace operation or a rapid thermal process. The gate insulator material may have a thickness in the range of approximately 3 nm to 15 nm. Gate material is then deposited over the gate insulator. In some examples, the gate material is deposited using a gate deposition process using any of a number of silane-based precursors. Polycrystalline silicon is one example of a material for the gate, however, a metal gate or a CMOS-based replacement gate process can also be used to form the gate.

After deposition of the gate insulator material and the gate material, a gate masking layer may be formed over the gate material and the underlying gate insulator material where the final gate and gate insulator should remain. Portions of the gate insulator material and the gate material which are exposed by the one or more gate masking layers are then removed (e.g., using a plasma etch or other suitable etch process) to define the final gate and gate insulator, and the one or more gate masking layers are then removed. In some examples, lightly doped drain regions are formed after patterning the gates, e.g., implanting n-type dopant species self-aligned at the edge of patterned gates. Subsequently, gate spacers may be formed on the sidewalls of the patterned gates.

In some examples, forming the gate spacers may be followed by formation of a source/drain mask layer that exposes portions of the well region (e.g., well region 112 or well region 162) and the drain drift region (e.g., drain drift region 116 or drain drift region 166) and the well region (e.g., well region 112 or well region 162) where the source region (e.g., source region 110 or source region 160) and the drain region (e.g., drain region 114 or drain region 164) are to be formed, respectively. An implantation process is then performed to implant n-type dopants within the exposed areas of the well region and the drain drift region to form the source region and the drain region. The source/drain mask layer is then removed.

After forming the source and drain regions, the silicide layers (e.g., silicide layers 124, 126 and 128 or silicide layers 174, 176 and 178) are then formed over the source region, the drain region and the gate. In some examples, the silicide layers are formed by forming a metal layer, which forms a metal silicide at temperatures consistent with silicon processing conditions, followed by heating of the structure to form a metal silicide. Unreacted portions of the metal layer are then removed, such as using a wet stripping process.

The ILD (e.g., ILD 130 or ILD 180) is then deposited over the structure. The ILD is formed of a dielectric material. A contact masking layer is then formed over the ILD to expose regions of the ILD where the conductive vias (e.g., conductive vias 132, 134 and 136 or conductive vias 182, 184 and 186) are to be formed. Exposed regions of the ILD are then removed, followed by filling of the conductive vias, followed by removal of the contact masking layer. The conductive vias are formed of a suitable metal such as tungsten. Additional metal interconnects may be formed as desired to construct a metal interconnect system for the structure.

While FIGS. 2A-2L, 3A-3L and 4A-4E respectively show process flows for formation of asymmetric graded STI layers prior to formation of a source region (e.g., source region 110 or source region 160), a well region (e.g., well region 112 or well region 162), a drain region (e.g., drain region 114 or drain region 164) and a drain drift region (e.g., drain drift region 116 or drain drift region 166), this is by way of example only. In other examples, the asymmetric graded STI layers may be formed subsequent to formation of a drain region, a drain drift region, a source region and a well region. Further, asymmetric graded STI layers may be formed using various other types of processing other than that shown in FIGS. 2A-4E.

In addition, while in accordance with illustrated implementations, various features or components have been shown as having particular arrangements or configurations, other arrangements and configurations are possible. Moreover, aspects of the present technology described in the context of example implementations may be combined or eliminated in other implementations. Thus, the breadth and scope of the description is not limited by any of the above-described implementations.

What is claimed is:

1. A semiconductor device, comprising:
a semiconductor layer;
a source region disposed in the semiconductor layer;
a drain region disposed in the semiconductor layer;
an insulating layer disposed in the semiconductor layer between the source region and the drain region, the insulating layer having a first sidewall extending toward the source region and a second sidewall extending toward the drain region, the first sidewall having a first slope and the second sidewall having a second slope greater than the first slope; and
a gate disposed over the semiconductor layer between the source region and the drain region, the gate covering a portion of the insulating layer.

2. The semiconductor device of claim 1, wherein the insulating layer comprises a shallow trench isolation region.

3. The semiconductor device of claim 1, wherein the insulating layer comprises an oxide material.

4. The semiconductor device of claim 1, wherein the insulating layer comprises a nitride material.

5. The semiconductor device of claim 1, wherein at least a portion of the gate extends past an edge of the insulating layer towards the source region.

6. The semiconductor device of claim 1, wherein at least a portion of the insulating layer extends past an edge of the gate towards the drain region.

7. The semiconductor device of claim 1, wherein the first sidewall of the insulating layer has a first length and the second sidewall of the insulating layer has a second length less than the first length.

8. The semiconductor device of claim 1, wherein the insulating layer has a non-sloped portion extending between the first sidewall and the second sidewall.

9. The semiconductor device of claim 1, wherein the semiconductor device comprises a laterally-diffused metal-oxide semiconductor (LDMOS) transistor.

10. A semiconductor device, comprising:
a semiconductor layer;
a source region disposed in the semiconductor layer;
a drain region disposed in the semiconductor layer;
an asymmetric graded shallow trench isolation layer disposed in the semiconductor layer between the source region and the drain region, the asymmetric graded shallow trench isolation layer having a first sloped section extending toward the source region and a second sloped section extending toward the drain region; and
a gate disposed over the semiconductor layer between the source region and the drain region, the gate covering a portion of the asymmetric graded shallow trench isolation layer.

11. The semiconductor device of claim 10, wherein the first sloped section of the asymmetric graded shallow trench isolation layer has a first length and the second sloped section of the asymmetric graded shallow trench isolation layer has a second length less than the first length.

12. The semiconductor device of claim 10, wherein the asymmetric graded shallow trench isolation layer further comprises a non-sloped section between the first sloped section and the second sloped section.

13. The semiconductor device of claim 10, wherein a first slope of the first sloped section of the asymmetric graded shallow trench isolation layer is different than a second slope of the second sloped section of the graded shallow trench isolation layer.

14. The semiconductor device of claim 13, wherein the second slope is greater than the first slope.

15. A method of fabricating a semiconductor device, comprising:
forming an insulating layer in a semiconductor layer, the insulating layer having a first sidewall extending toward a first side and a second sidewall extending toward a second side opposite the first side, the first sidewall having a first slope and the second sidewall having a second slope greater than the first slope; and
forming a gate over the semiconductor layer, the gate covering a portion of the insulating layer;
forming a source region in the semiconductor layer, the source region proximate to the first side; and
forming a drain region in the semiconductor layer, the drain region proximate to the second side.

16. The method of claim 15, wherein forming the insulating layer comprises:
forming a first hard mask layer over the semiconductor layer;
forming a second hard mask layer over the first hard mask layer;
forming a first patterning layer over a portion of the second hard mask layer;
etching exposed portions of the second hard mask layer; and
removing the first patterning layer.

17. The method of claim 16, wherein forming the insulating layer further comprises:
forming a second patterning layer over a portion of the first hard mask layer, an edge of the second patterning layer proximate the second hard mask layer defining an edge of the first sidewall of the insulating layer proximate the second side;
performing two or more iterations of: (i) performing a partial etch of an exposed portion of the first hard mask layer; and (ii) laterally trimming the second patterning layer to expose an additional portion of the first hard mask layer;
removing the second patterning layer;
transferring a pattern of the first hard mask layer to a trench in the semiconductor layer; and
forming insulating material for the insulating layer in the trench.

18. The method of claim 16, wherein forming the insulating layer further comprises:
forming a second patterning layer over the first hard mask layer and a portion of the second hard mask layer, an edge of the second patterning layer proximate the second hard mask layer defining an edge of the first sidewall of the insulating layer proximate the second side;
performing two or more iterations of: (i) performing a partial etch of exposed portions of the first hard mask layer and the second hard mask layer; and (ii) laterally trimming the second patterning layer to expose an additional portion of at least one of the first hard mask layer and the second hard mask layer;
removing the second patterning layer;
transferring a pattern of the first hard mask layer to a trench in the semiconductor layer; and
forming insulating material for the insulating layer in the trench.

19. The method of claim 15, wherein forming the insulating layer comprises:
forming a photoresist layer over the semiconductor layer;
generating a pattern in the photoresist layer utilizing a mask device comprising a light-passing substrate and a patterned opaque layer disposed on the light-passing substrate, the patterned opaque layer comprising a light modulating region for defining the first slope of the first sidewall and the second slope of the second sidewall; and
transferring the pattern of the photoresist layer to a trench in the semiconductor layer; and
forming insulating material for the insulating layer in the trench.

20. The method of claim 19, wherein the light modulating region comprises a set of features, wherein at least a subset of the set of features are disposed at differing distances from one another for defining at least one of the first slope of the first sidewall and the second slope of the second sidewall.
